(19) United States
(12) Patent Application Publication
(10) Pub. No.: US 2026/0304751 A1
(43) Pub. Date: Oct. 1, 2026

(54) SEMICONDUCTOR STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: YU-CHIEN CHIU, HSINCHU COUNTY (TW); CHEN-JUN WU, HSINCHU CITY (TW); YA-YUN CHENG, TAICHUNG CITY (TW); CHIEN-HAO HUANG, HSINCHU CITY (TW); WEN-LING LU, TAOYUAN CITY (TW); KATHERINE H. CHIANG, NEW TAIPEI CITY (TW); CHUNG-WEI WU, HSIN-CHU COUNTY (TW); ZHIQIANG WU, HSINCHU COUNTY (TW)

(21) Appl. No.: 19/093,303

(22) Filed: Mar. 28, 2025

(51) Int. Cl. H10B 12/00; H10D 30/63; H10D 62/10; H10D 62/17; H10D 64/27

(52) U.S. Cl. CPC H10B 12/33; H10B 12/036; H10B 12/05; H10D 30/63; H10D 62/112; H10D 62/292; H10D 64/516

(57) ABSTRACT

A semiconductor structure is provided. The semiconductor structure includes a lower dielectric layer, a middle dielectric layer and an upper dielectric layer. The lower dielectric layer includes a plurality of first conductive regions electrically connecting memory elements and a plurality of first barrier structures formed on bottoms or tops of the plurality of first conductive regions. The middle dielectric layer includes channel regions and each includes a channel layer and a gate electrode, which are separated by a gate dielectric layer. The channel layer electrically connects the first conductive region. The gate electrode is formed between the lower dielectric layer and the upper dielectric layer. The upper dielectric layer includes a plurality of second conductive regions electrically connecting the channel layer and a plurality of second barrier structures formed on bottoms or tops of the plurality of second conductive regions. The first and second barrier structures include hydrogen absorption materials.

### BACKGROUND

Non-volatile memory generally refers to any memory or storage that can retain stored data even when no power is applied. Exemplary non-volatile memories include flash memories, which are widely used in memory cards and USB drives to store data and to transfer data between a computer and other digital devices, such as cameras and mobile phones. Flash memories often implement floating gate transistors, which generally include a metal-oxide-semiconductor field effect transistor (MOSFET) capacitively coupled to a number of secondary gates (such as control gates). Because the floating gate is electrically isolated from the secondary gates, any charge trapped on the floating gate is retained for a long period of time without any power supply. Charge stored on the floating gate can be altered by applying voltages to source, drain, and/or secondary gates. Nanocrystal charge trap structures are currently being explored for providing the charge trapping region in the floating gate, as such structures can improve charge retention, operate at room temperature, and facilitate quick access. Although existing non-volatile memory devices implementing nanocrystal charge trap structures and methods for fabricating such have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A illustrates a perspective view of a semiconductor structure, in accordance with some embodiments of the present disclosure.

FIG. 1B illustrates a cross-sectional front view of a semiconductor structure of FIG. 1A, in accordance with some embodiments of the present disclosure.

FIG. 2A illustrates a perspective view of a semiconductor structure, in accordance with some embodiments of the present disclosure.

FIG. 2B illustrates a cross-sectional front view of a semiconductor structure of FIG. 2A, in accordance with some embodiments of the present disclosure.

FIG. 3A illustrates a perspective view of a semiconductor structure, in accordance with some embodiments of the present disclosure.

FIG. 3B illustrates a cross-sectional front view of a semiconductor structure of FIG. 3A, in accordance with some embodiments of the present disclosure.

FIG. 4A illustrates a perspective view of a semiconductor structure, in accordance with some embodiments of the present disclosure.

FIG. 4B illustrates a cross-sectional front view of a semiconductor structure of FIG. 4A, in accordance with some embodiments of the present disclosure.

FIG. 5A illustrates a perspective view of a semiconductor structure, in accordance with some embodiments of the present disclosure.

FIG. 5B illustrates a cross-sectional front view of a semiconductor structure of FIG. 5A, in accordance with some embodiments of the present disclosure.

FIG. 6A illustrates a partial cross-sectional side view of the semiconductor structure in accordance with some another embodiments of the present disclosure.

FIG. 6B illustrates a cross-sectional front view of the semiconductor structure of FIG. 6A, in accordance with some another alternative embodiments of the present disclosure.

FIG. 7A illustrates a partial cross-sectional side view of the semiconductor structure in accordance with some alternative embodiments of the present disclosure.

FIG. 7B illustrates a cross-sectional front view of the semiconductor structure of FIG. 7A, in accordance with some another alternative embodiments of the present disclosure.

FIG. 8 is a flowchart of a method for forming the semiconductor structure in accordance with some embodiments.

FIGS. 9A to 9W illustrate various perspective views of forming the semiconductor structure in accordance with some embodiments as described in FIG. 8.

FIGS. 10A to 10W illustrate cross-sectional front views of the semiconductor structure shown in FIGS. 9A to 9W, respectively, in accordance with some embodiments of the present disclosure.

FIG. 11 illustrates a perspective view showing details along line A-A of the semiconductor structure shown in FIG. 9D in accordance with some embodiments of the present disclosure.

FIG. 12 illustrates a perspective view showing details along line B-B of the semiconductor structure shown in FIG. 9G in accordance with some embodiments of the present disclosure.

FIG. 13 illustrates a perspective view showing details along line B-B of the semiconductor structure shown in FIG. 9G in accordance with some another embodiments of the present disclosure.

FIG. 14 illustrates a plot showing device currents of a semiconductor structure with plurality of first barrier structures and a plurality of second barrier structures in accordance with some embodiments of the present disclosure (curve A) and a semiconductor structure without barrier structures (curve B).

FIG. 15 illustrates a plot showing negative bias temperature instability (NBTI) stress results of a semiconductor structure with a plurality of first barrier structures and a plurality of second barrier structures in accordance with some embodiments of the present disclosure (curve A) and a semiconductor structure without barrier structures (curve B).

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

A one-transistor one-capacitor (1T1C) memory cell is a type of memory comprising a capacitor and a transistor. The capacitor stores varying levels of charge which correspond to an individual bit of data stored in the capacitor, and the transistor facilitates access to the capacitor for read and write operations. The relatively simple structure of the 1T1C memory cell allows high memory density, which leads to high memory capacity and a low cost per bit. 1T1C memory cells are typically used with dynamic random-access memory (DRAM).

The transistor of a 1T-1C DRAM cell may include a metal-oxide channel (e.g., a channel layer that includes a metal-oxide material). The use of a metal-oxide channel may provide reduced current leakage in the 1T-1C DRAM cell relative to an elemental semiconductor channel or a III-V compound semiconductor channel, which may improve charge retention (and thus, data retention) in the capacitor of the 1T-1C DRAM cell. However, metal-oxide materials are highly susceptible to hydrogen contamination. During the fabrication of the 1T-1C DRAM cell, hydrogen may be present, such as atmospheric hydrogen and/or hydrogen that is used in various types of deposition processes, such as a chemical vapor deposition (CVD), atomic layer deposition (ALD), or anneal process. Because of the small size of hydrogen and the high mobility of hydrogen, hydrogen ions (e.g., H⁺) may diffuse into the metal-oxide channel of the 1T-1C DRAM cell and charge carrier concentration can increase in the metal-oxide channel. The increased charge carrier concentration can cause increased off-current leakage for the 1T-1C DRAM cell, increased positive bias temperature instability (PBTI), and/or increased negative bias temperature instability (NBTI). Hydrogen diffusion in the metal-oxide channel would result in high leakage, worse reliability and increased contact resistance, leading to slower writing and reading speeds. Hydrogen contamination in the metal-oxide channel would also increase the charge carrier concentration to a point where the 1T-1C DRAM cell becomes stuck in a normally-on configuration, thereby rendering the 1T-1C DRAM cell non-operational. Therefore, there is a need to provide a semiconductor structure, which eliminates hydrogen diffusion in the metal-oxide channel to enhance the performance of the semiconductor structure.

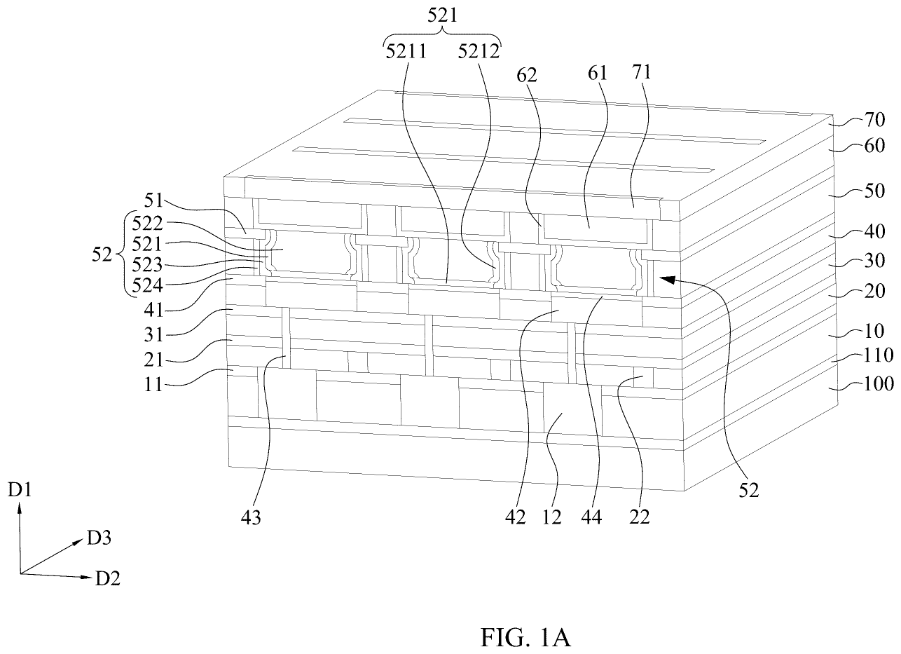

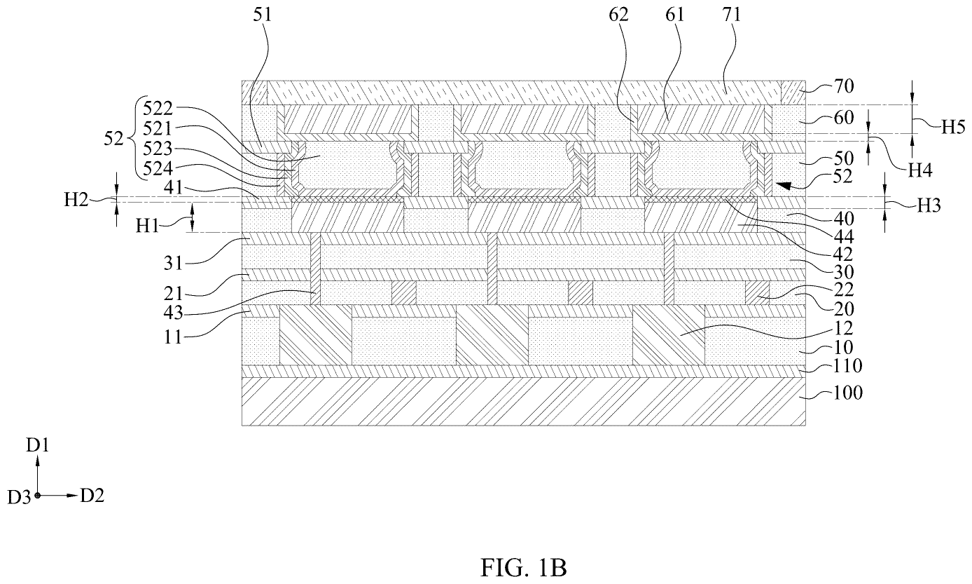

Referring to FIGS. 1A and 1B, the semiconductor structure comprises a plurality of dielectric layers 10, 20, 30, 40, 50 and 60 and a plurality of insulating layers 11, 21, 31, 41, 51 stacking alternately along a first direction D1. In some embodiments, the semiconductor structure comprises a first dielectric layer 10, a second dielectric layer 20 comprising first conductive lines 22, a third dielectric layer 30, a fourth dielectric layer 40, a fifth dielectric layer 50 and a sixth dielectric layer 60, which are separated by a first insulating layer 11, a second insulating layer 21, a third insulating layer 31, a fourth insulating layer 41 and a fifth insulating layer 51, and a seventh dielectric layer 70. The number of dielectric layers and the number of insulating layer can be adjusted as needed.

The first dielectric layer 10 can be formed on a substrate 100, which is fabricated in the front-end-of-line (FEOL). The substrate 100 can be overlaid with a lower insulating layer 110. The first dielectric layer 10 is overlaid with the first insulating layer 11 and comprises a plurality of memory elements 12. The plurality of memory elements 12 are formed in the first dielectric layer 10. A top portion of each of the plurality of memory elements 12 is surrounded by the first insulating layer 11, so that the plurality of memory elements 12 are exposed from the first insulating layer 11. The first dielectric layer 10 may include a dielectric material such as, but not limited to, oxide, a low-k material, or combinations thereof. For example, the first dielectric layer 10 may include, but not limited to, silicon oxide (SiO₂), hafnium silicate (HfSiO₄), zirconium silicate (ZrSiO₄), or combinations thereof. The first insulating layer 11 may include, but not limited to a metal oxide or an oxidized metal such as such as AlOₓ (such as Al₂O₃), WOₓ, HfOₓ (such as HfO₂), or the like, or combinations thereof.

The second dielectric layer 20 is formed over the first insulating layer 11 and the plurality of memory elements 12. The second dielectric layer 20 can be overlaid with the second insulating layer 21 and may comprise a plurality of first conductive lines 22. The plurality of first conductive lines 22 are formed in the second dielectric layer 20 and on the first insulating layer 11 so as to located between the first insulating layer 11 and the second insulating layer 21. The plurality of first conductive lines 22 may be arranged in parallel along a second direction D2, perpendicular to the first direction D1, and may be functioned as word lines (WL). The plurality of first conductive lines 22 comprises conductive materials. In some embodiments, the second dielectric layer 20 may comprise materials identical or similar to materials of the first dielectric layer 10. The second insulating layer 21 may comprise materials identical or similar to materials of the first insulating layer 11.

The third dielectric layer 30 is formed over the second insulating layer 21. The third dielectric layer 30 can be overlaid with the third insulating layer 31. In some embodiments, the third dielectric layer 30 may comprise materials identical or similar to materials of the second dielectric layer 20. The third insulating layer 31 may comprise materials identical or similar to materials of the second insulating layer 21.

The fourth dielectric layer 40 is formed over the third insulating layer 31. The fourth dielectric layer 40 can be overlaid with the fourth insulating layer 41 and may comprises a plurality of first conductive regions 42 and a plurality of first barrier structures 44. The plurality of first conductive region 42 are formed on the third insulating layer 31 and connect to the memory elements 12 by a plurality of connecting lines 43, each extending from the first conductive region 42, through the third insulating layer 31, the third dielectric layer 30, the second insulating layer 21 and the second dielectric layer 20, to the memory element 12. In some embodiments, a top portion of each of the plurality of first conductive regions 42 is surrounded by the fourth insulating layer 41, so that a top of each of the plurality of first conductive region 42 is exposed from the fourth insulating layer 41. In some embodiments, the first conductive regions 42 may be referred to as source/drain regions. In some embodiments, the first conductive regions 42 can be referred to as source regions. In some embodiments, the first conductive regions 42 comprise tungsten (W), copper (Cu), titanium nitride (TiN), tantalum nitride (TaN), aluminum (Al), ruthenium (Ru), cobalt (Co), indium tin oxide (ITO), doped semiconductor material (e.g., p-doped or n-doped silicon), and/or other metals. The plurality of connecting lines 43 may comprise materials identical or similar to the materials of the first conductive regions 42. In some embodiments, the fourth dielectric layer 40 may comprise materials identical or similar to materials of the third dielectric layer 30. The fourth insulating layer 41 may comprise materials identical or similar to the materials of the third insulating layer 31.

Each of the plurality of first barrier structures 44 corresponds to one of the first conductive regions 42. As shown in FIGS. 1A and 1B, each of the first barrier structures 44 can be a film formed on the first conductive region 42 and thus may be surrounded by the third insulating layer 31. In some embodiments, the first barrier structure 44 may have a thickness H2 (shown in FIG. 1B), which may be substantially equal to or less than a thickness H1 of the first conductive region 42. In some embodiments, a ratio of the thickness H1 of the first conductive region 42 to the thickness H2 of the first barrier structure 44 may range from about 15:1 to about 1:1. In some embodiments, the ratio of the thickness H1 of the first conductive region 42 to the thickness H2 of the first barrier structure 44 may range from about 10:1 to about 2:1. In some embodiments, the ratio of the thickness H1 of the first conductive region 42 to the thickness H2 of the first barrier structure 44 may range from about 7:1 to about 4:1. In some embodiments, the thickness H2 of the first barrier structure 44 may be substantially equal to or less than a thickness H3 of the third insulating layer 31. In some embodiments, a ratio of the thickness H3 of the third insulating layer 31 to the thickness H2 of the first barrier structure 44 may range from about 5:1 to about 1:1. In some embodiments, the ratio of the thickness H3 of the third insulating layer 31 to the thickness H2 of the first barrier structure 44 may range from about 10:3 to about 5:4. In some embodiments, the ratio of the thickness H3 of the third insulating layer 31 to the thickness H2 of the first barrier structure 44 may range from about 2:1 to about 5:3. In some embodiments, the thickness H2 of the first barrier structure 44 may range from about 1 nm to about 100 nm. In some embodiments, the thickness H2 of the first barrier structure 44 may range from about 3 nm to about 80 nm. In some embodiments, the thickness H2 of the first barrier structure 44 may range from about 5 nm to about 50 nm.

The first barrier structure 44 may comprise hydrogen absorption materials, including but not limited to indium oxide (InO), titanium oxide (TiO), ITO, cerium oxide (CeO), zinc oxide (ZnO), indium gallium zinc oxide (IGZO), a combination thereof and so on.

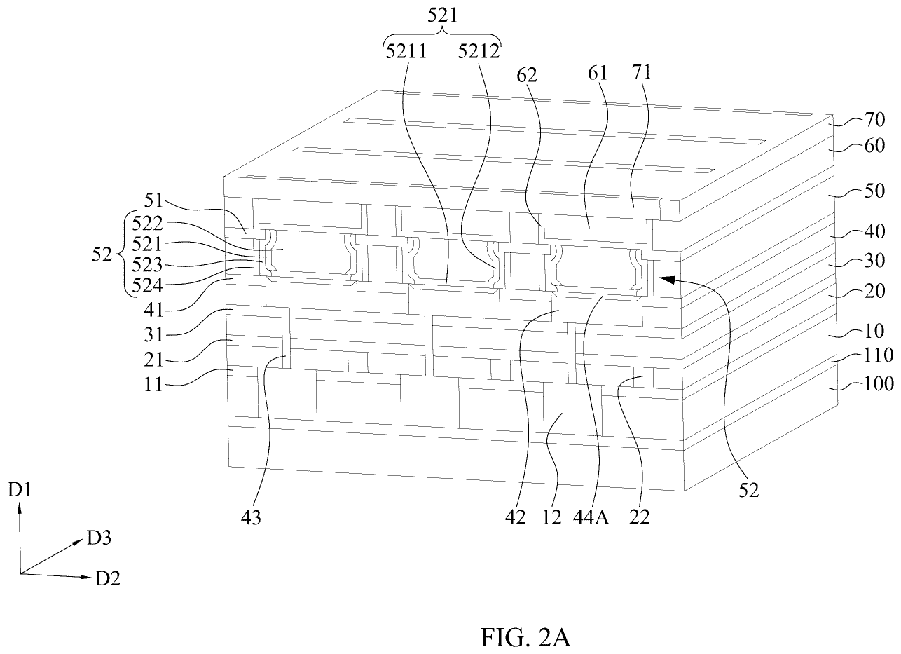

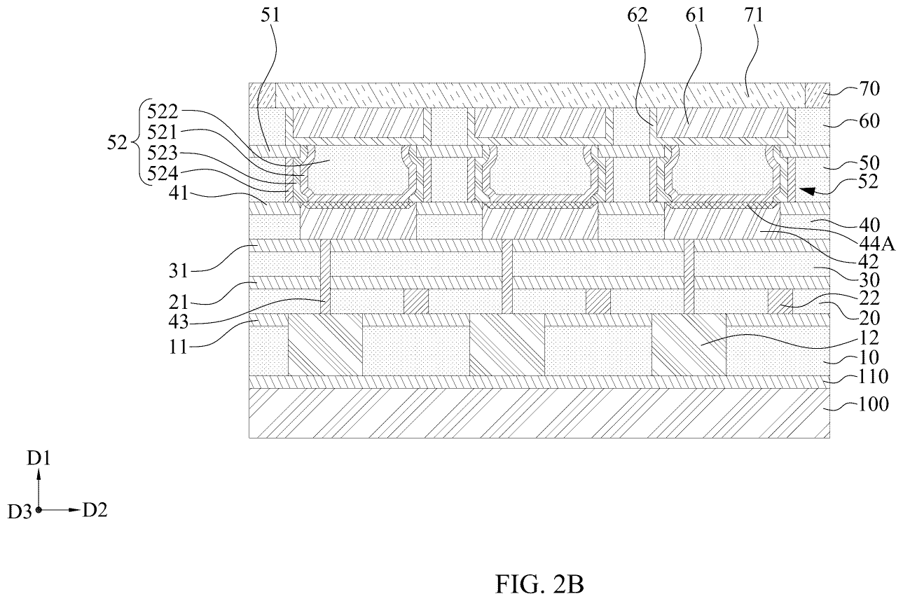

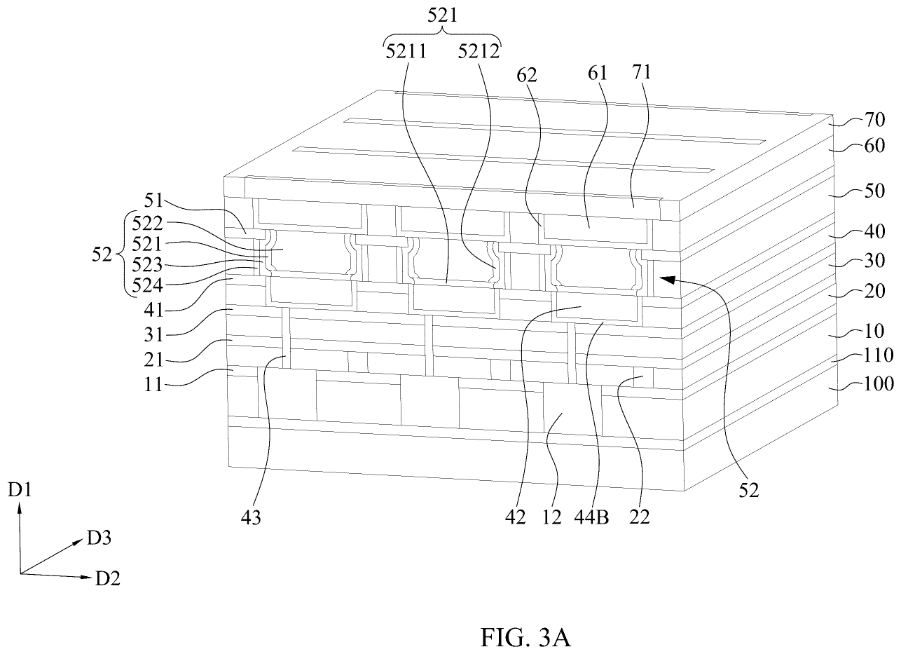

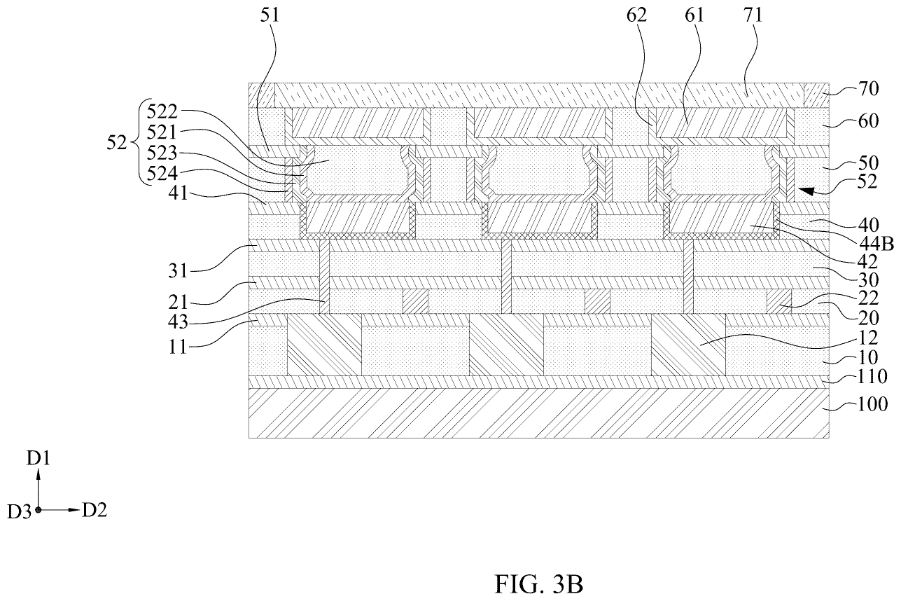

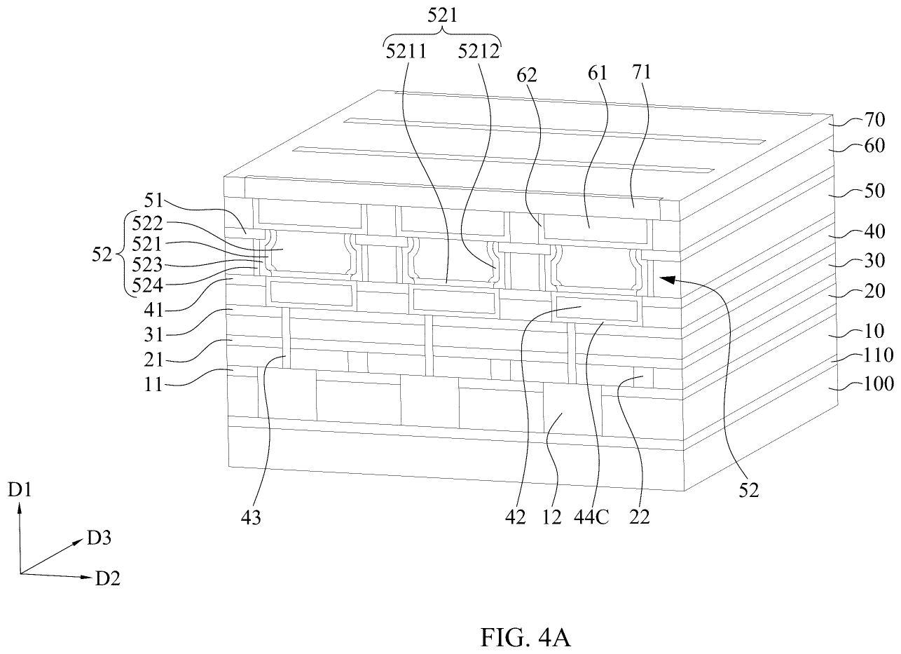

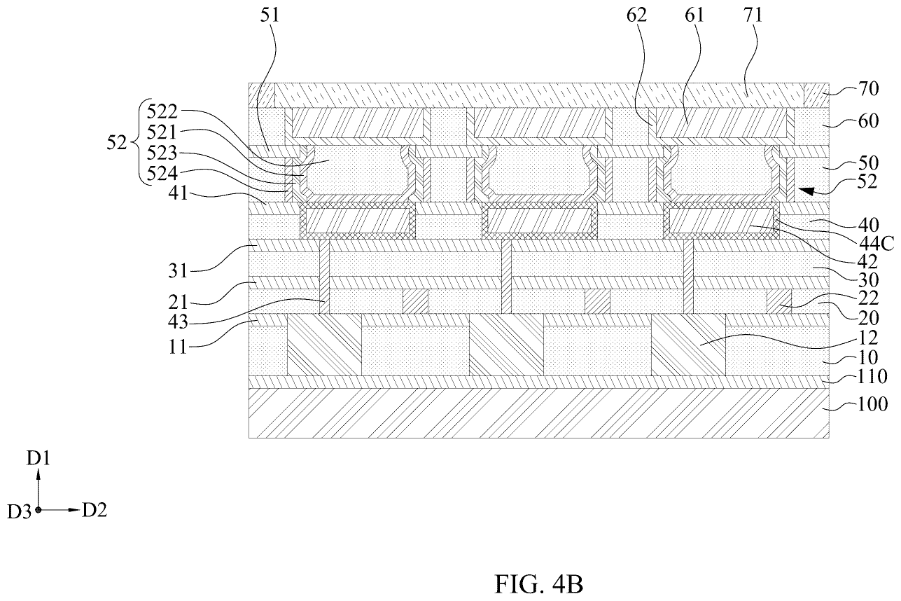

In some embodiments as illustrated in FIGS. 1A and 1B, the first barrier structure 44 may have a rectangular cross section from the front view. In some another embodiments as illustrated in FIGS. 2A and 2B, the first barrier structure 44A may have an inverted-trapezoid cross section from the front view. In some another embodiments as illustrated in FIGS. 3A and 3B, the first barrier structure 44B may be formed between the first conductive region 42 and the third insulating layer 31, between the first conductive region 42 and the fourth dielectric layer 40 and between the first conductive region 42 and the third insulating layer 31 so as to serve as a bottom and sidewalls of the first conductive region 42. The first barrier structure 44B may have a U-shape cross section from the front view. In some another embodiments as illustrated in FIGS. 4A and 4B, the first barrier structure 44C may be formed on the first conductive region 42, between the first conductive region 42 and the third insulating layer 31, between the first conductive region 42 and the fourth dielectric layer 40 and between the first conductive region 42 and the third insulating layer 31 so as to surround the first conductive region 42 and serve as a top, a bottom and sidewalls of the first conductive region 42.

The fifth dielectric layer 50 is formed over the fourth insulating layer 41 and the first conductive region 42. The fifth dielectric layer 50 can be overlaid with the fifth insulating layer 51. In some embodiments, the fifth dielectric layer 50 may comprise materials identical or similar to materials of the fourth dielectric layer 40. The fifth insulating layer 51 may comprise materials identical or similar to the materials of the fourth insulating layer 41. The fifth dielectric layer 50 comprises a plurality of channel regions 52. Each of the plurality of channel regions 52 comprises a central portion, gate dielectric layers 523 and gate electrodes 524. The central portion of the channel region 52 is formed over the first conductive region 42. In some embodiments, as shown in FIGS. 3A and 3B, the central portion of the channel region 52 contacts the first conductive region 42. The central portion of the channel region 52 comprises a channel layer 521 and a central isolation structure 522. The channel layer 521 has a U shape and serves as a bottom and a sidewall of the central isolation structure 522. In some embodiments, the channel layer 521 has a bottom segment 5211 and sidewalls 5212. The sidewalls 5212 may be linear, curved, or other regular or irregular configuration. In some embodiments, as shown in FIGS. 1A, 1B, 2A, 2B, 4A and 4B, the central portion of the channel region 52, such as the channel layer 521 (i.e., the bottom segment 5211) contacts the first barrier structure 44 formed on the first conductive region 42. The central isolation structure 522 is formed on the bottom segment 5211 of the channel layer 521 and is sandwiched by the sidewalls 5212 of the channel layer 521. The central isolation structure 522 has a configuration corresponding to the configuration of the sidewalls 5212 of the channel layer 521. In some embodiments as shown in FIGS. 1A and 1B, the central isolation structure 522 may have an oblate shape with narrower top and bottom than middle portion.

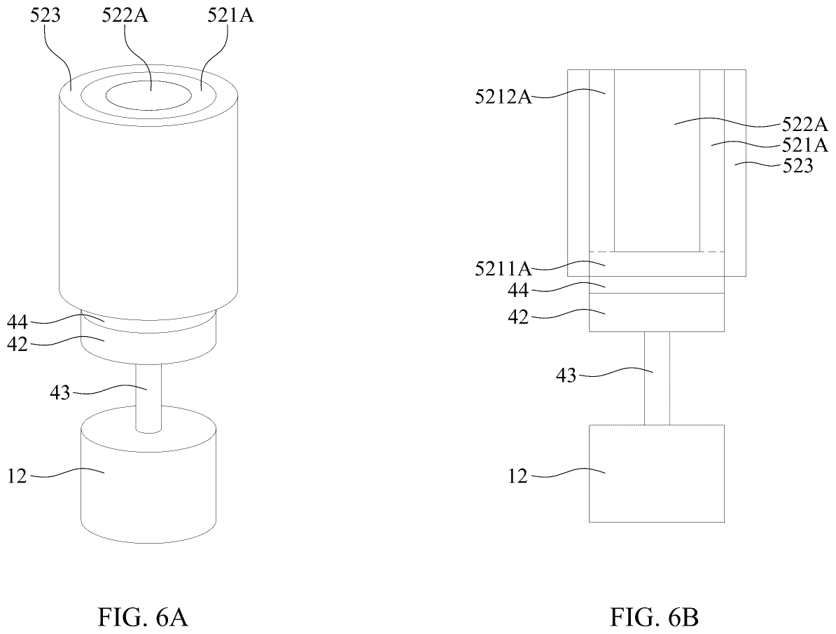

Embodiments of the central portion of the channel region 52 can be provided. For example, the central portion may include a channel layer 521A and a central isolation structure 522A, as shown in FIGS. 6A and 6B. In some embodiments, sidewalls 5212A of the channel layer 521A are linear and the central isolation structure 522A may have a rectangular cross section from the front view. The channel layer 521A are also linear corresponding to the sidewalls 5212A of the channel layer 521A. In some embodiments, the channel layer 521A is a single layer. In an alternative embodiments, the channel layer may have two or more channel sublayers.

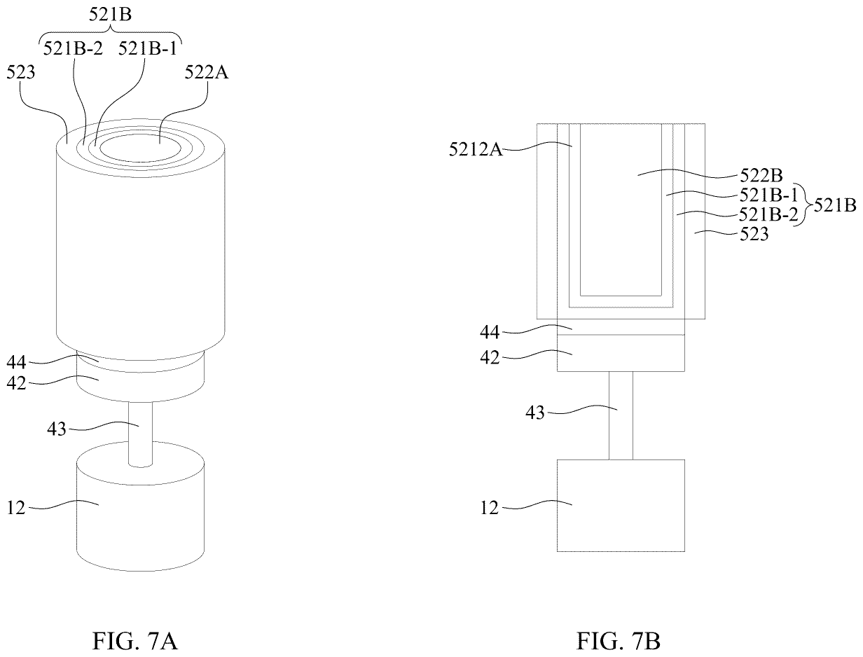

In some embodiments, the central portion may include a channel layer 521B and a central isolation structure 522B, as shown in FIGS. 7A and 7B. In such embodiments, the channel layer 521B comprises a first channel sublayer 521B-1 and a second channel sublayer 521B-2. The first channel sublayer 521B-1 surrounds a bottom and the sidewalls of the central isolation structure 522B and may have a first doping concentration. The second channel sublayer 521B-2 surrounds the first channel sublayer 521B-1 and is formed between the first channel sublayer 521B-1 and the gate dielectric layers 523 and between the first channel sublayer 521B-1 and the first barrier structure 44 on the first conductive region 42. The second channel sublayer 521B-2 may have a second doping concentration, which may be greater or less than the first doping concentration. In some embodiments, the second doping concentration is greater than the first doping concentration, so the second channel sublayer 521B-2 may be highly doped or highly doped with p-type dopants or n-type dopants. The second channel sublayer 521B-2 can be a high doping channel and the first channel sublayer 521B-1 can be a low doping channel. These are, of course, merely examples and are not intended to be limiting.

The channel layer 521, 521A, 521B may be an N-type channel or a P-type channel. When the channel layer 521, 521A, 521B is an N-type channel, the channel layer 521, 521A, 521B may comprise IGZO, ZnO, In₂O₃, SnO₂, and so on. When the channel layer 521, 512A, 521B is a P-type channel, the channel layer 521, 521A, 521B may comprise NiO, Cu₂O, CuAlO₂, CuGaO₂, CuInO₂, SrCu₂O₂, SnO, and so on. In some embodiments, the central isolation structure 522, 522A, 522B may comprise material identical or similar to materials of the first dielectric layer 10, the second dielectric layer 20, the third dielectric layer 30, the fourth dielectric layer 40, or the fifth dielectric layer 50. In some embodiments, the central isolation structure 522, 522A, 522B may comprise material identical to the fifth dielectric layer 50. In some embodiments, the central isolation structure 522, 522A, 522B may comprise material identical to the sixth dielectric layer 60.

The gate dielectric layers 523 are formed around the channel layers 521 and contacts the fifth insulating layer 51 so that the channel layer 521 is sandwiched by the gate dielectric layer 523 and the central isolation structure 522. Each of the gate dielectric layers 523 is partially formed over the first conductive region 42 and partially formed on the fourth insulating layer 41. The gate dielectric layer 523 may be formed of a high-k dielectric material, such as metal oxides, including but not limited to hafnium oxide (HfO2), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), SiO2, Al2O3, metal nitrides, metal silicates, transition metal-oxides, transition metal-nitrides, transition metal-silicates, oxynitrides of metals, metal aluminates, zirconium silicate, zirconium aluminate, zirconium oxide, titanium oxide, aluminum oxide, hafnium dioxide-alumina (HfO₂-Al₂O₃) alloy, other suitable high-k dielectric materials, or combinations thereof. Alternatively, the gate dielectric layer 523 may include silicon nitride, silicon oxynitride or silicon oxide. In some embodiments, the gate dielectric layer 523 may be formed using PVD, CVD or other suitable deposition methods. In some embodiments, the gate dielectric layer 523 may comprise HfO₂, SiO₂, Al₂O₃, SiON, and so on.

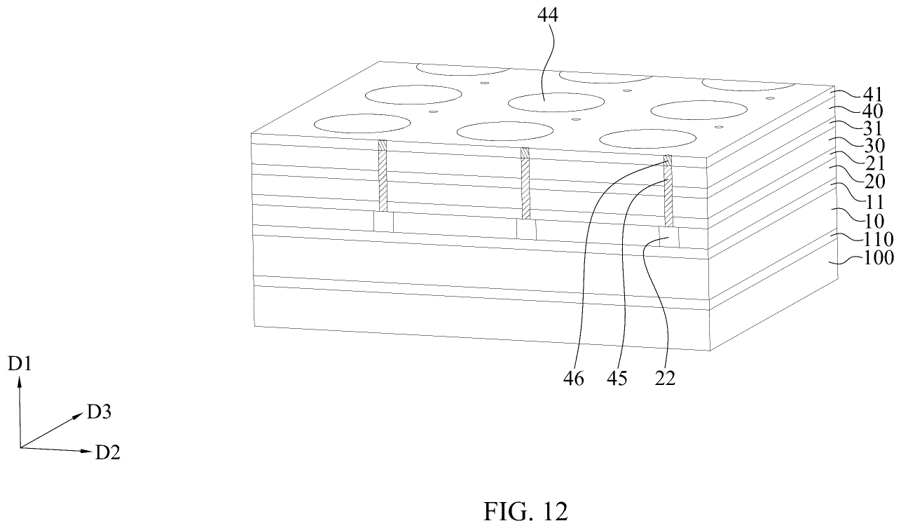

The gate electrodes 524 are formed along the gate dielectric layers 523 and between the fourth insulating layer 41 and the fifth insulating layer 51, so that each of the gate dielectric layers 523 is sandwiched by the gate electrode 524 and the channel layer 521. The gate electrodes 524 connect the first conductive lines 22 through vias 45 (as shown in FIG. 12). The gate electrode 524 may include a metallic material, polycrystalline silicon, doped silicon, or a metal compound, such as metal nitride. The metallic material may include, for example, but not limited to, tungsten (W), silver (Ag), aluminum (Al), copper, nickel (Ni), other suitable materials, alloys thereof, or combinations thereof. The metal compound may include, for example, but not limited to, titanium nitride (TiN), tantalum nitride (TaN), metal silicide, other suitable materials, or combinations thereof. Other suitable materials for fabricating the gate electrode are within the contemplated scope of the present disclosure.

The sixth dielectric layer 60 is formed over the fifth insulating layer 51 and the plurality of channel regions 52. In some embodiments, the sixth dielectric layer 60 may comprise materials identical or similar to materials of the fifth dielectric layer 50. The sixth dielectric layer 60 comprises a plurality of second conductive regions 61 and a plurality of second barrier structures 62. Each of the plurality of second conductive regions 61 is formed over the channel region 52 and may be partially or completely surrounded by the second barrier structure 62. In some embodiments, the second conductive regions 61 may be referred to as source/drain regions. In some embodiments, the first conductive region 42 can be referred to as a source region, and the second conductive regions 61 can be referred to as drain regions. In some embodiments, the second conductive regions 61 comprise tungsten (W), copper (Cu), titanium nitride (TiN), tantalum nitride (TaN), aluminum (Al), ruthenium (Ru), cobalt (Co), indium tin oxide (ITO), doped semiconductor material (e.g., p-doped or n-doped silicon), and/or other metals. The second conductive regions 61 may comprise materials identical or similar to the materials of the first conductive regions 42.

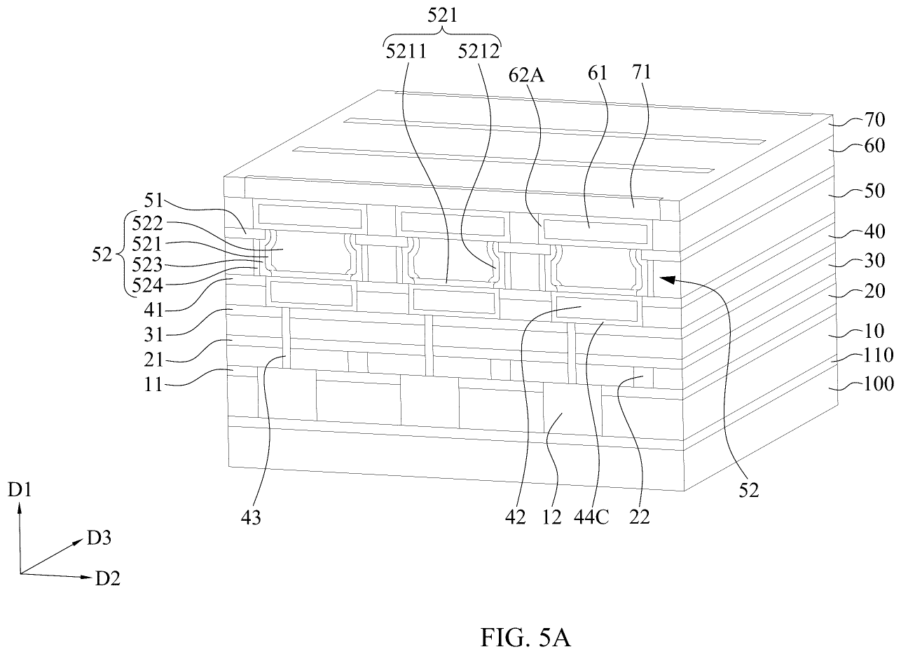

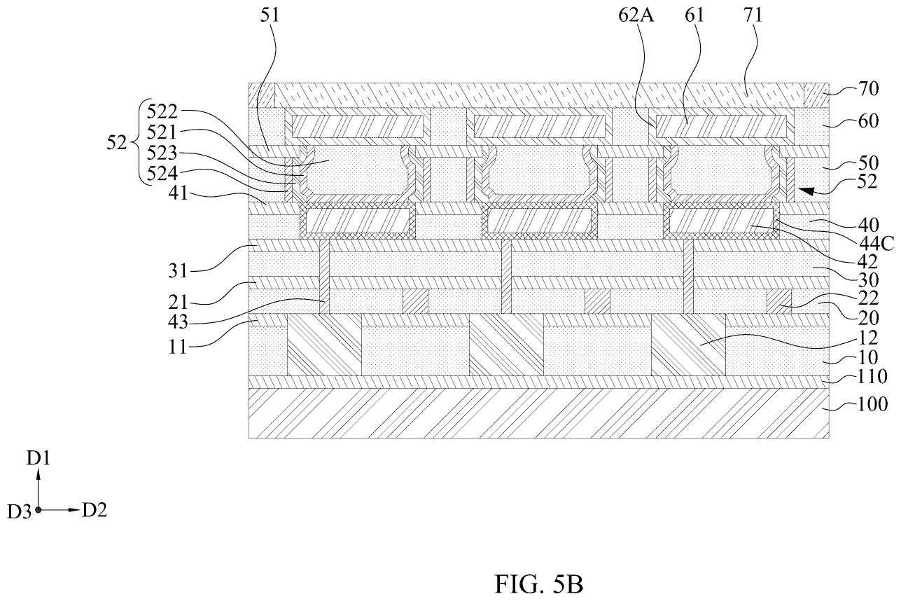

In some embodiments as shown in FIGS. 1A, 1B, 2A, 2B, 3A, 3B, 4A and 4B, the second barrier structure 62 may have a U-shape cross section from the front view and serves as a bottom and sidewalls of the second conductive regions 61, so that the second barrier structure 62 is sandwiched by the second conductive regions 61 and the channel region 52 and the sixth dielectric layer 60. In some embodiments as shown in FIGS. 5A and 5B, the second barrier structure 62A may completely surround the second conductive region 61 and serve as a top, a bottom and sidewalls of the second conductive region 61.

The second barrier structure 62 may comprise hydrogen absorption materials, such a metal-like materials, including but not limited to indium oxide (InO), titanium oxide (TiO), ITO, cerium oxide (CeO), zinc oxide (ZnO), indium gallium zinc oxide (IGZO) and so on. In some embodiments, the second barrier structure 62 may have a thickness H4 (shown in FIG. 1B), which may be substantially equal to or less than a thickness H5 of the second conductive region 61. In some embodiments, a ratio of the thickness H5 of the second conductive region 61 to the thickness H4 of the second barrier structure 62 may range from about 15:1 to about 1:1. In some embodiments, the ratio of the thickness H5 of the second conductive region 61 to the thickness H4 of the second barrier structure 62 may range from about 10:1 to about 2:1. In some embodiments, the ratio of the thickness H5 of the second conductive region 61 to the thickness H4 of the second barrier structure 62 may range from about 7:1 to about 4:1. In some embodiments, the thickness H4 of the second barrier structure 62 may range from about 1 nm to about 100 nm. In some embodiments, the thickness H4 of the second barrier structure 62 may range from about 3 nm to about 80 nm. In some embodiments, the thickness H4 of the second barrier structure 62 may range from about 5 nm to about 50 nm.

The seventh dielectric layer 70 is formed over the sixth dielectric layer 60 and the second conductive regions 61. The seventh dielectric layer 70 comprises a plurality of second conductive lines 71 arranged in parallel along a third direction D3, perpendicular to the first direction D1 and also perpendicular to the second direction D2. The plurality of second conductive lines 71 may be functioned as bit lines (BL). Each of the plurality of second conductive lines 71 connecting several second conductive regions 61. In some embodiments as shown in FIGS. 5A and 5B, the plurality of second conductive lines 71 may be formed on the second conductive regions 61 through the second barrier structure 62.

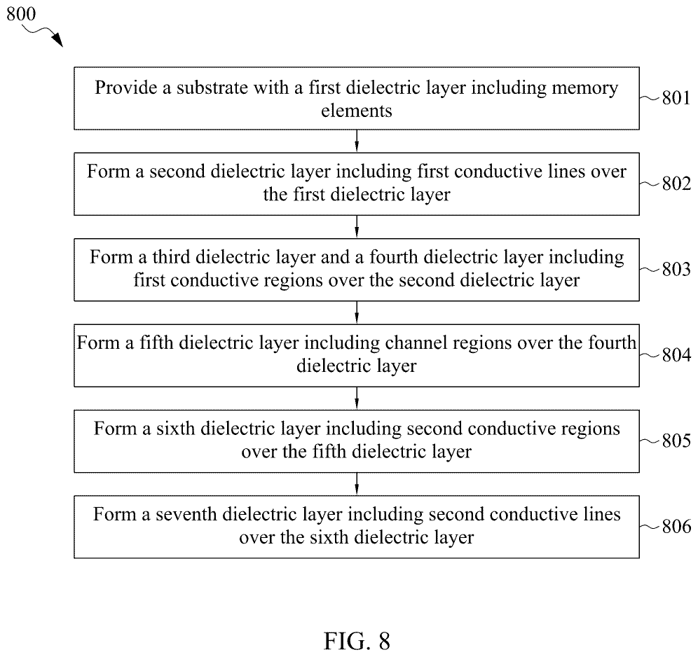

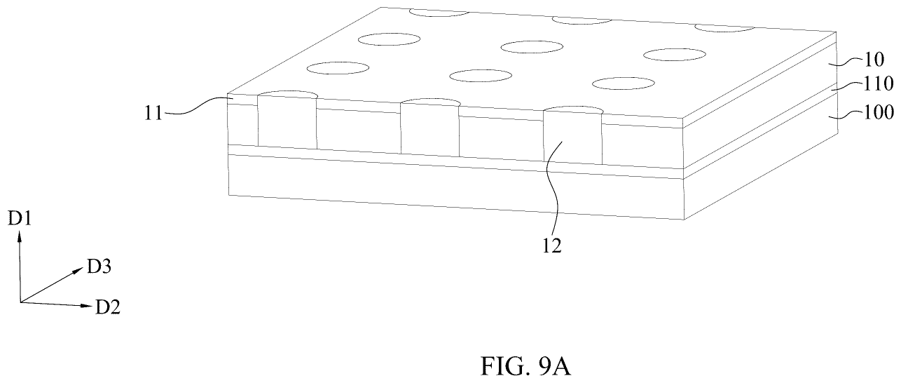

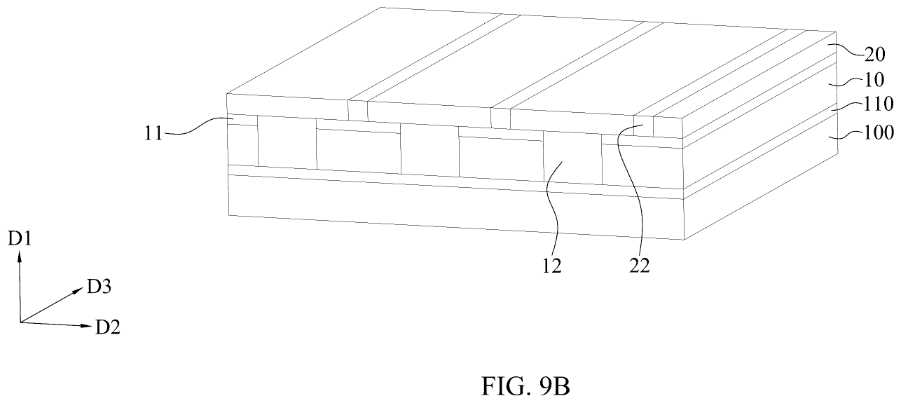

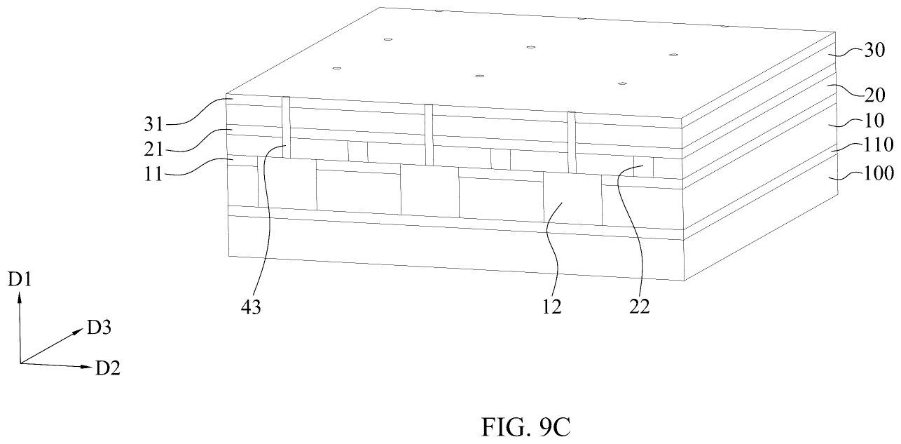

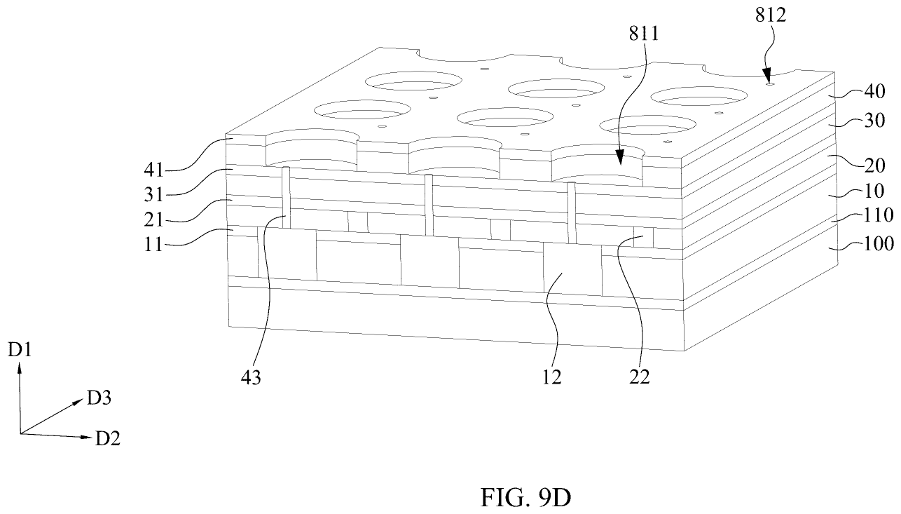

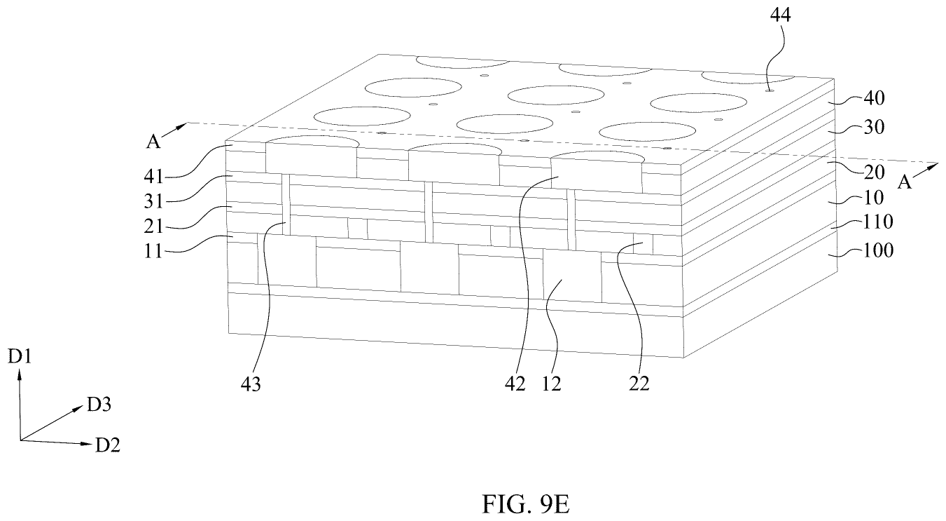

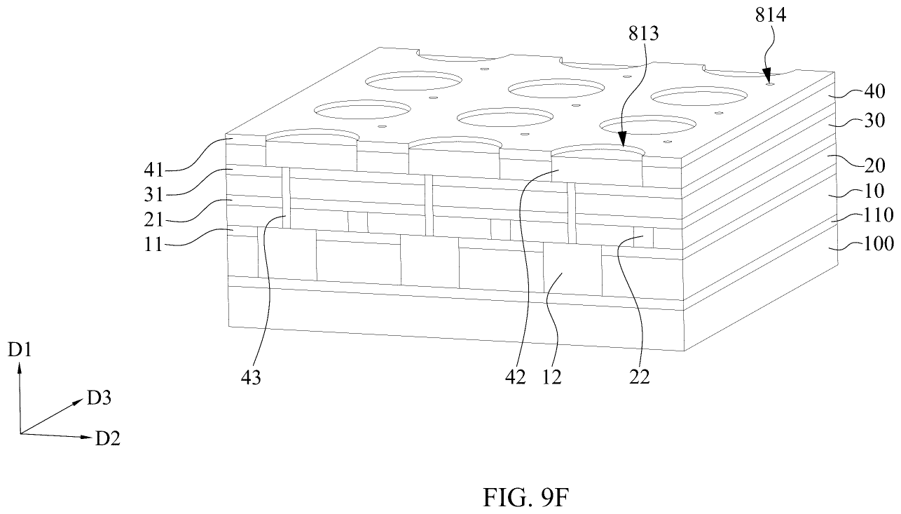

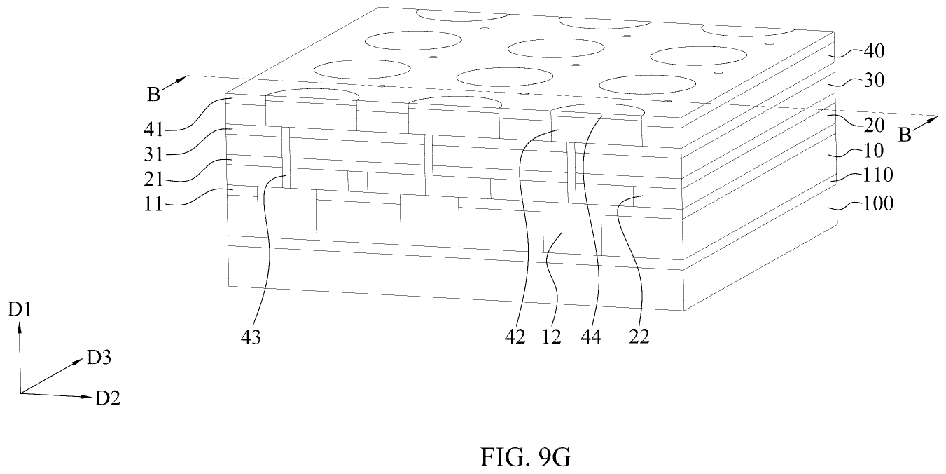

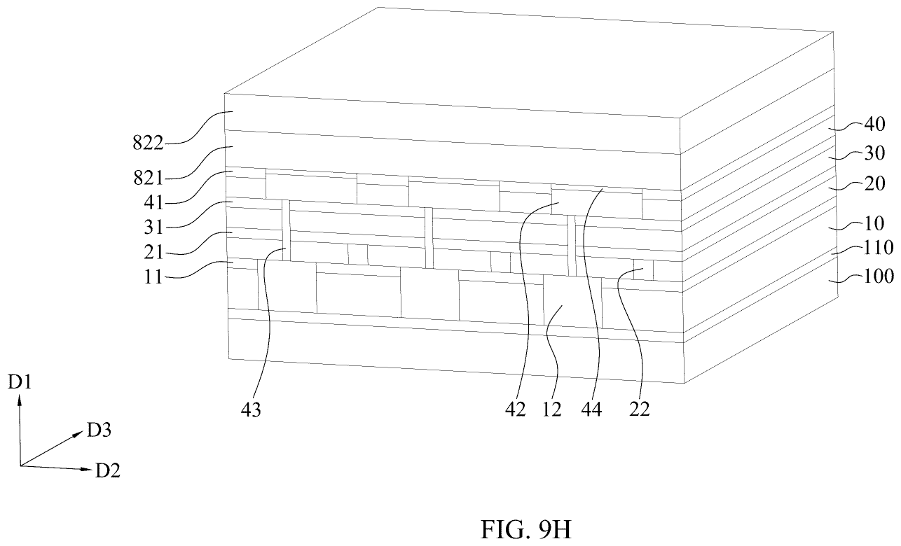

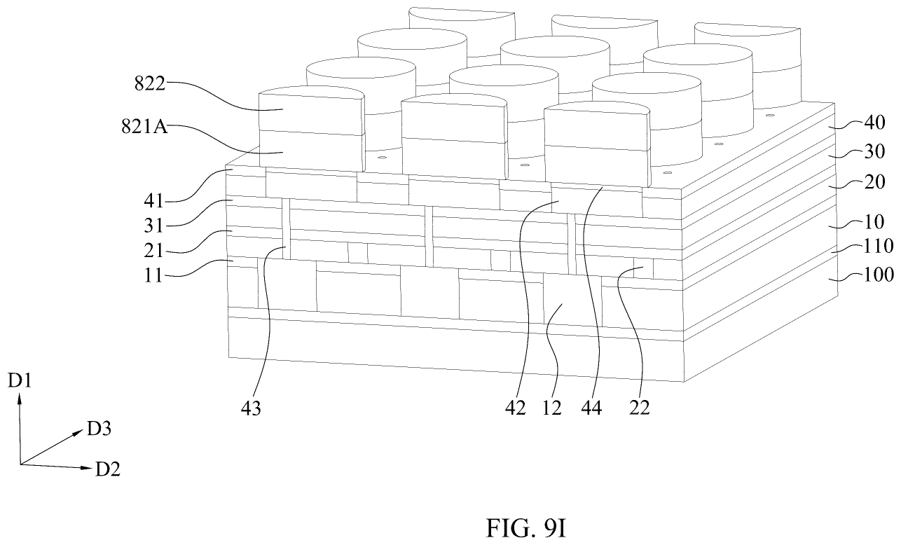

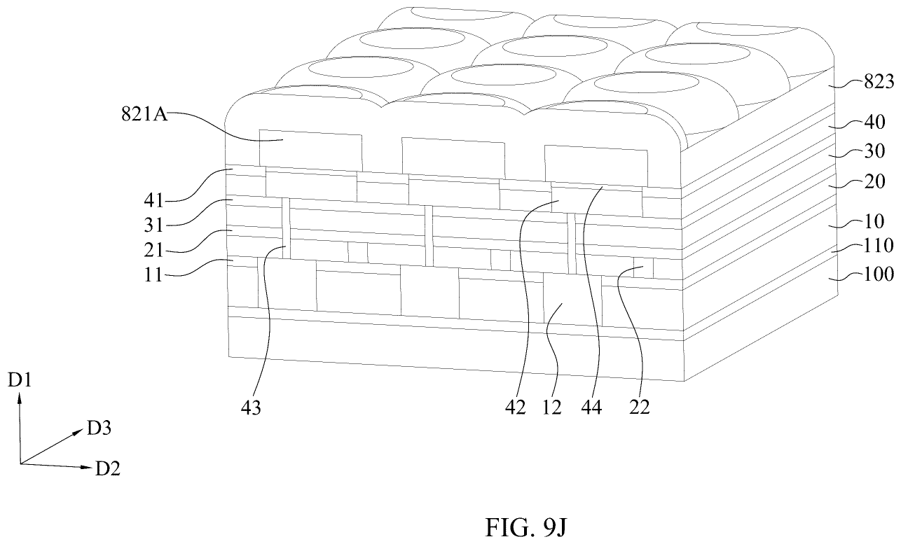

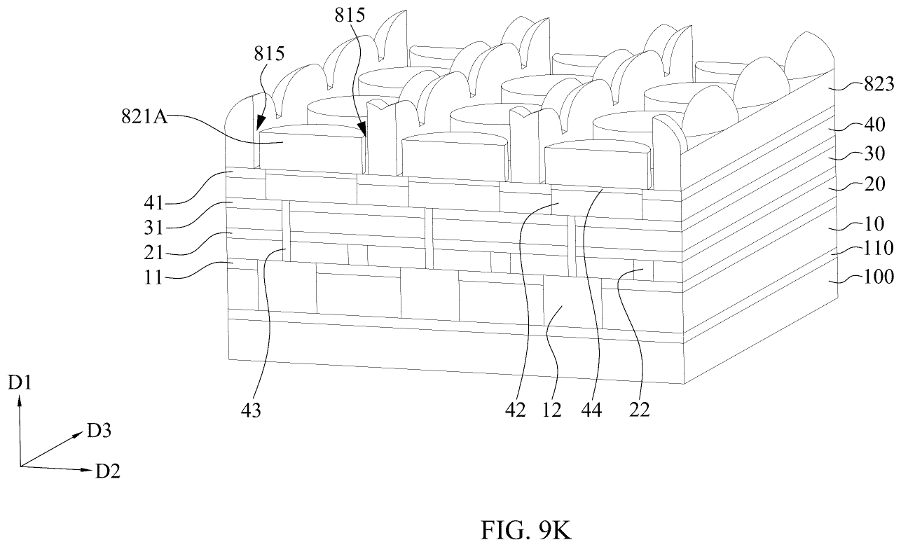

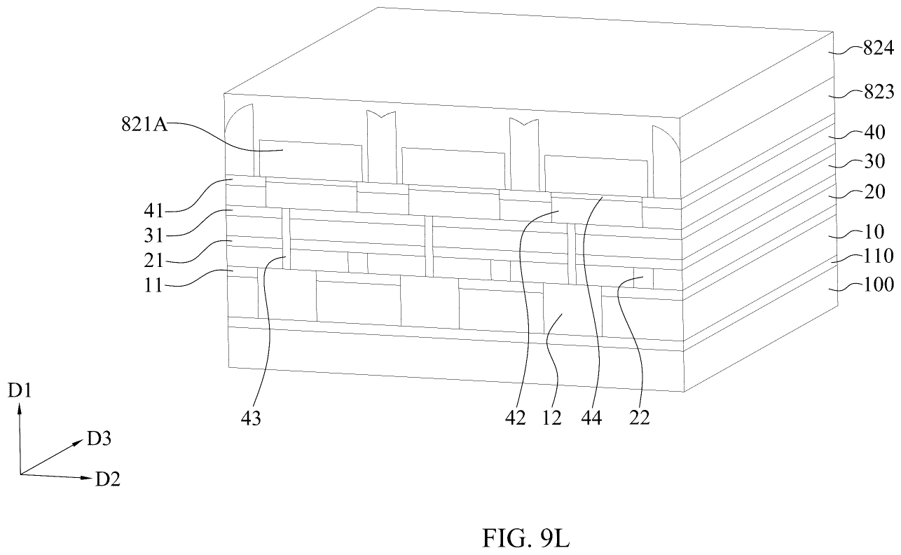

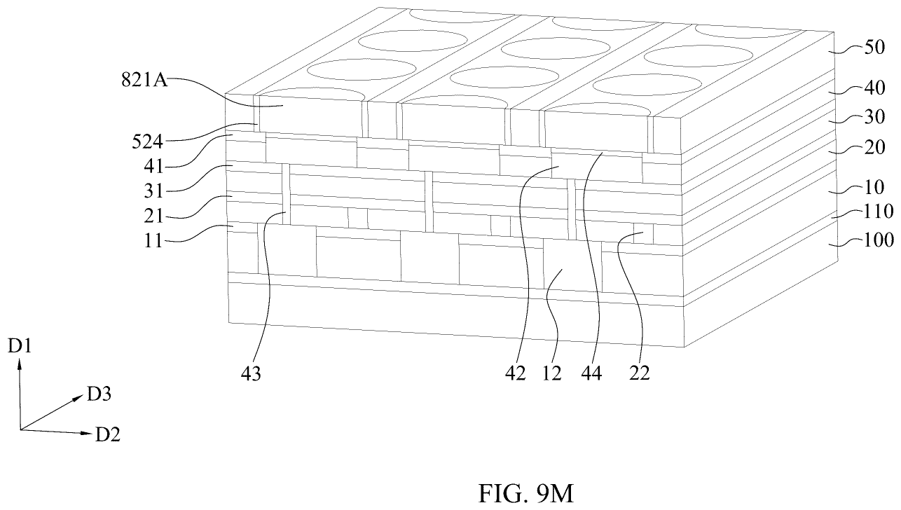

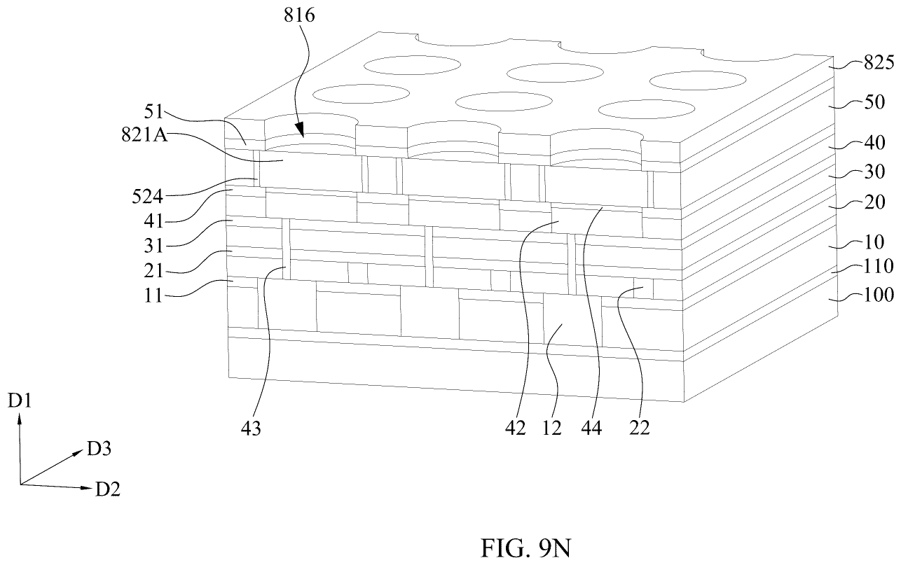

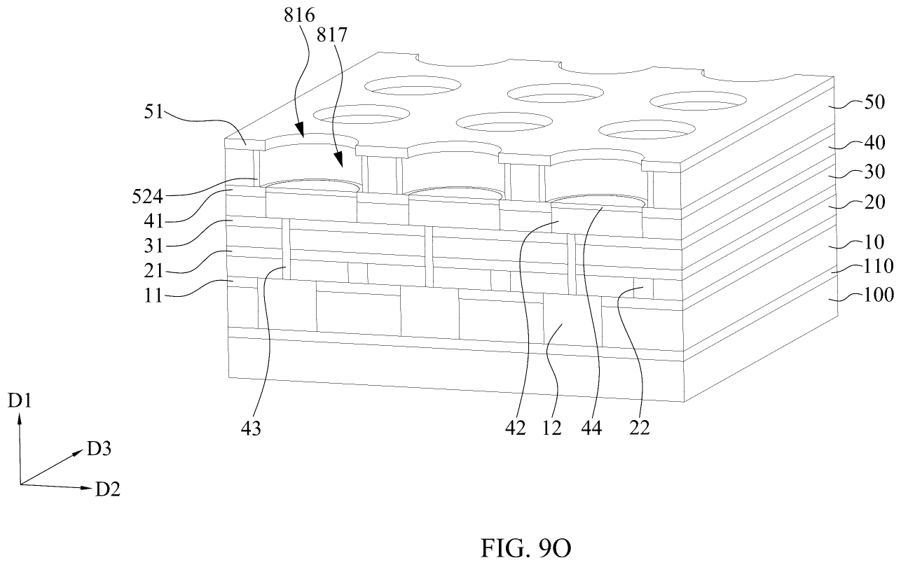

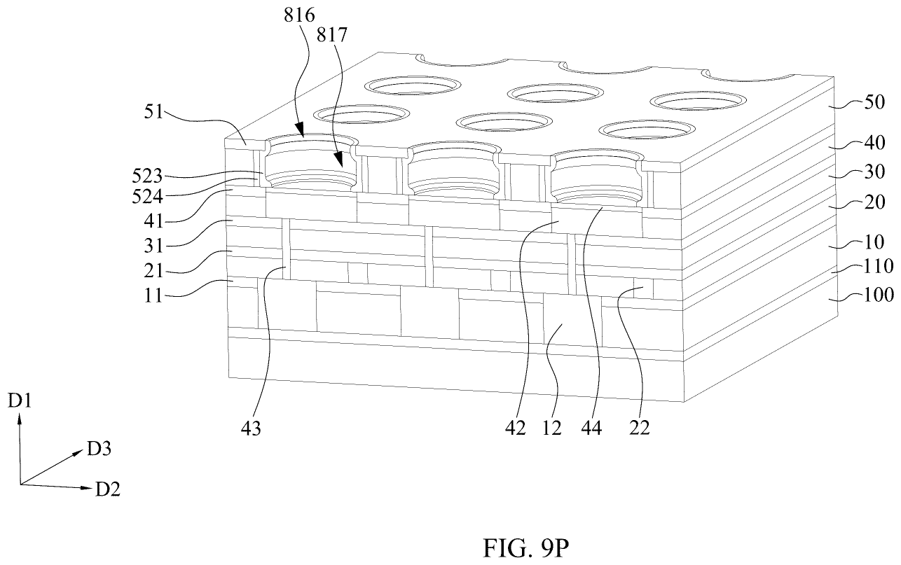

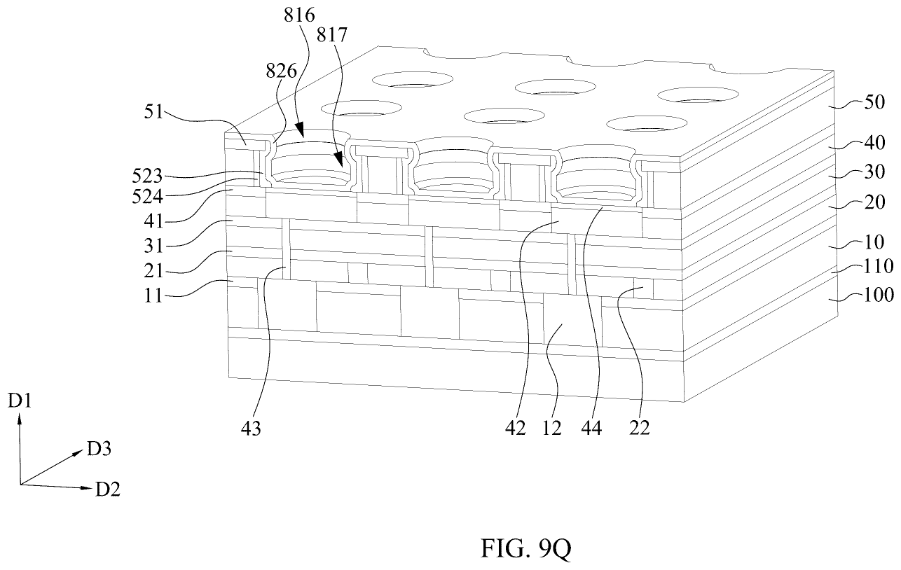

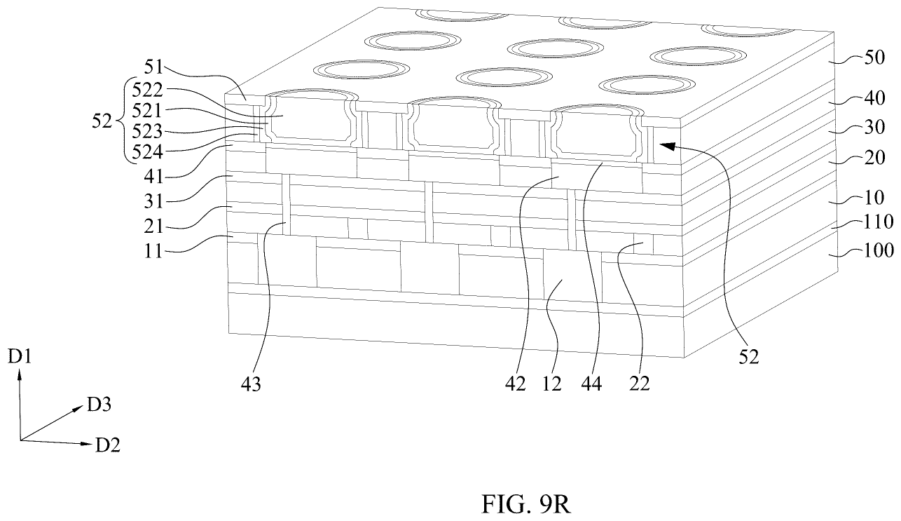

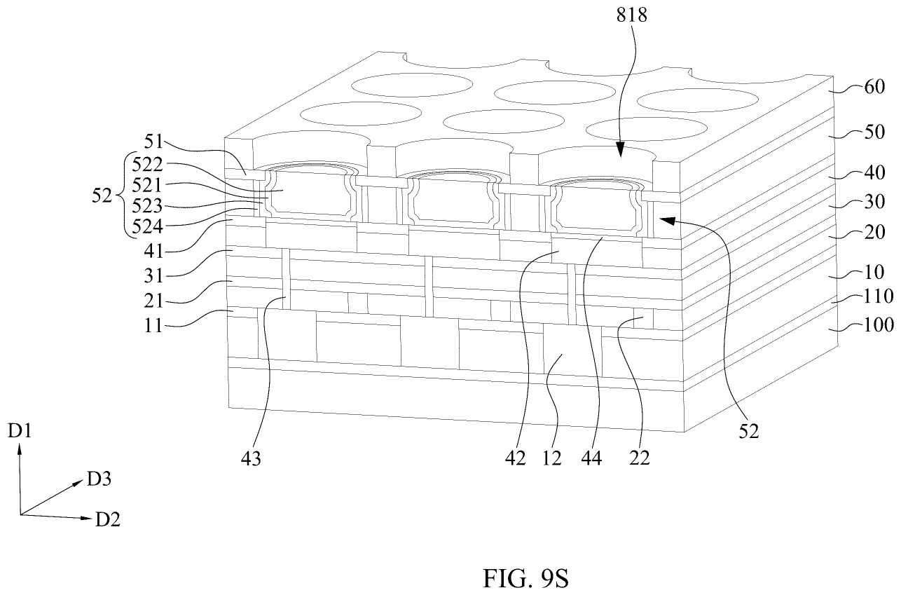

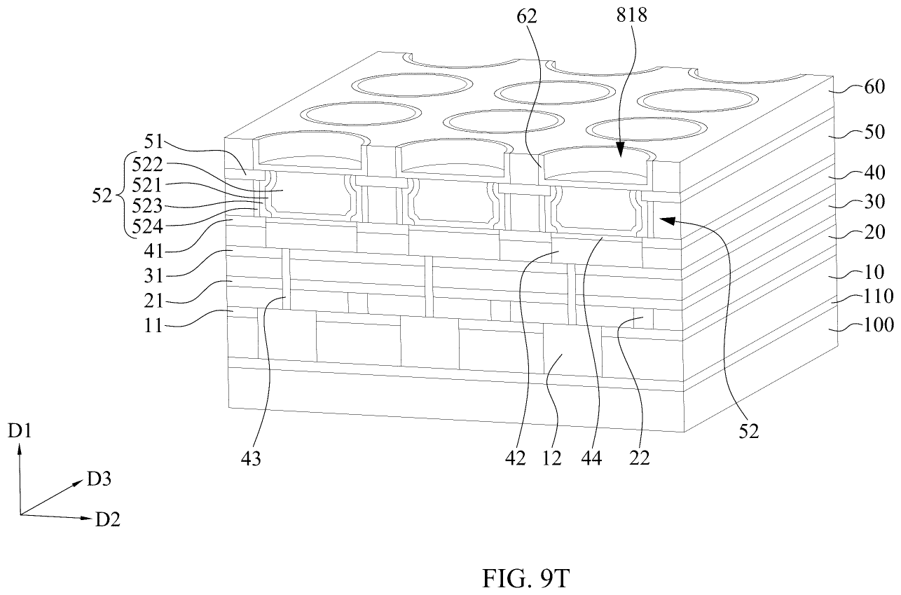

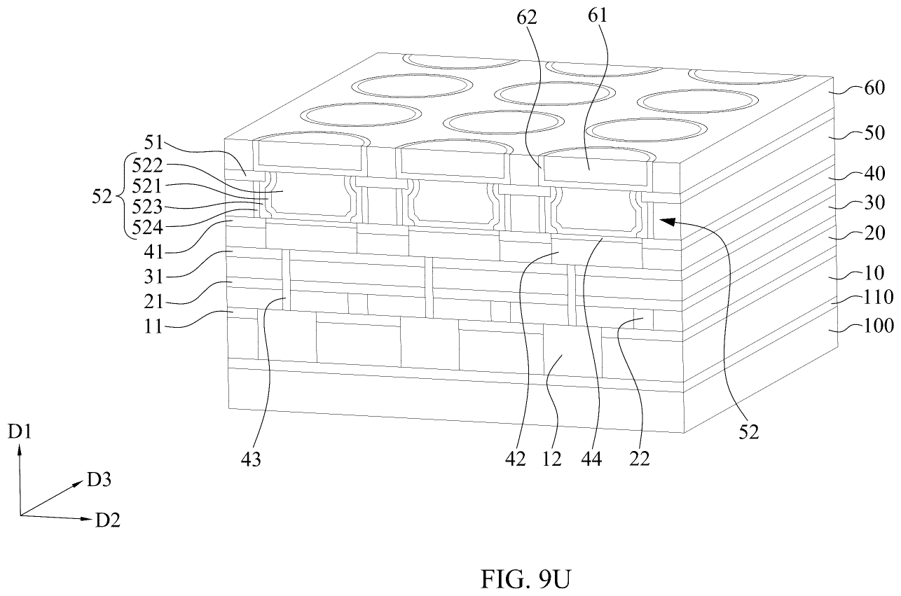

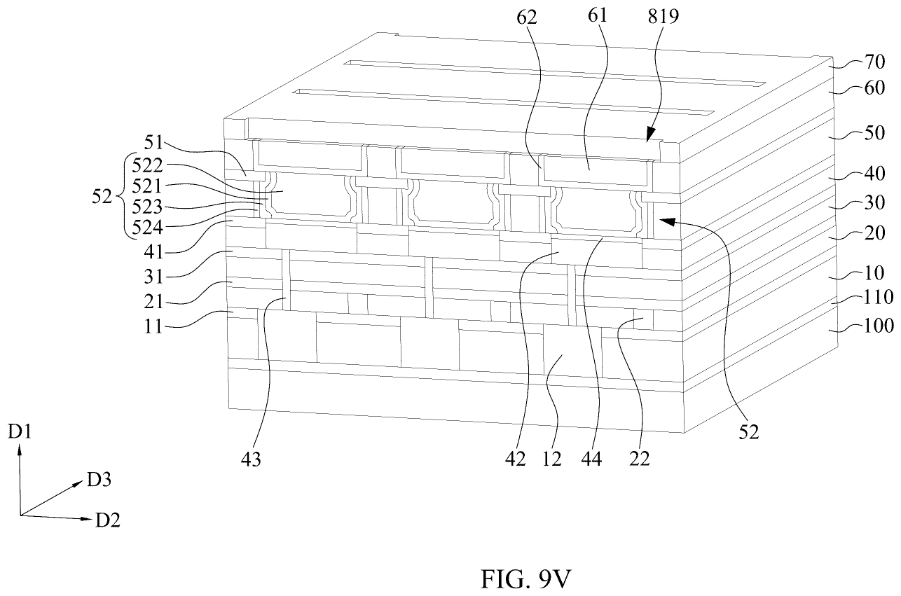

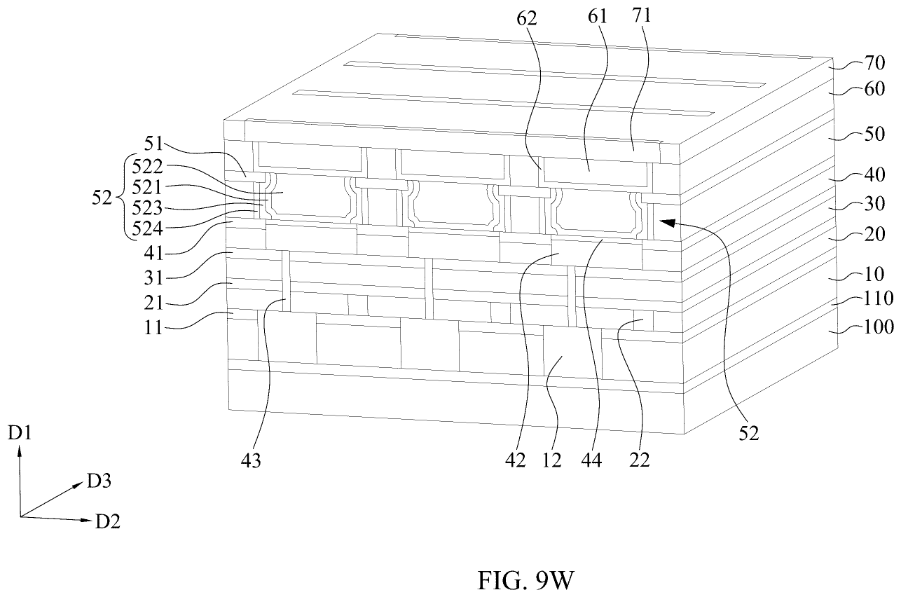

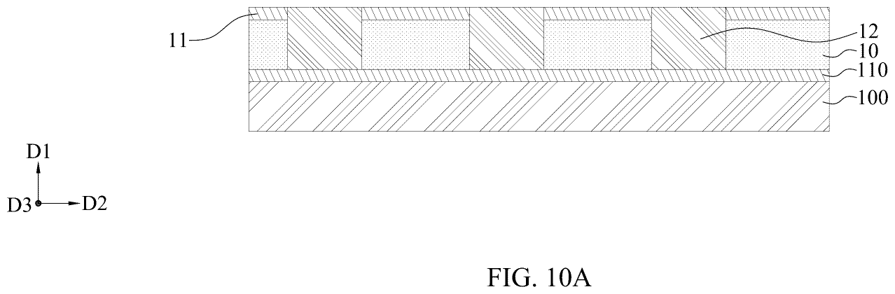

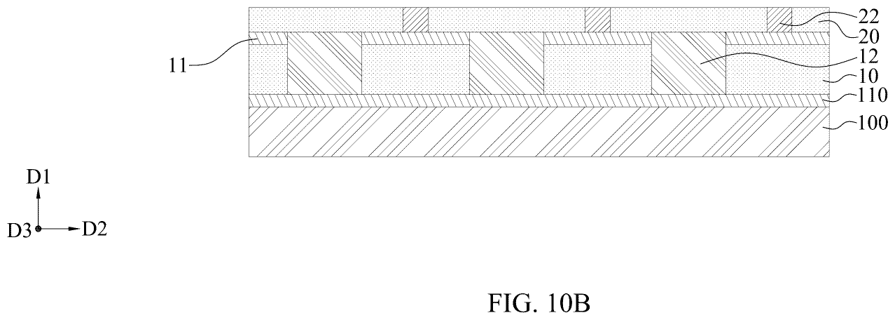

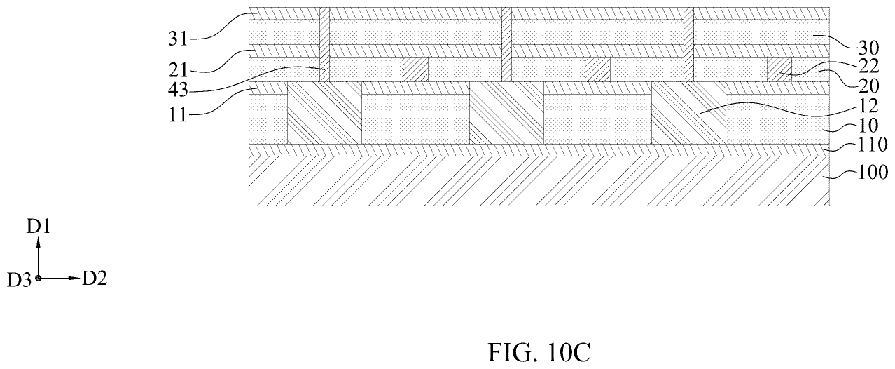

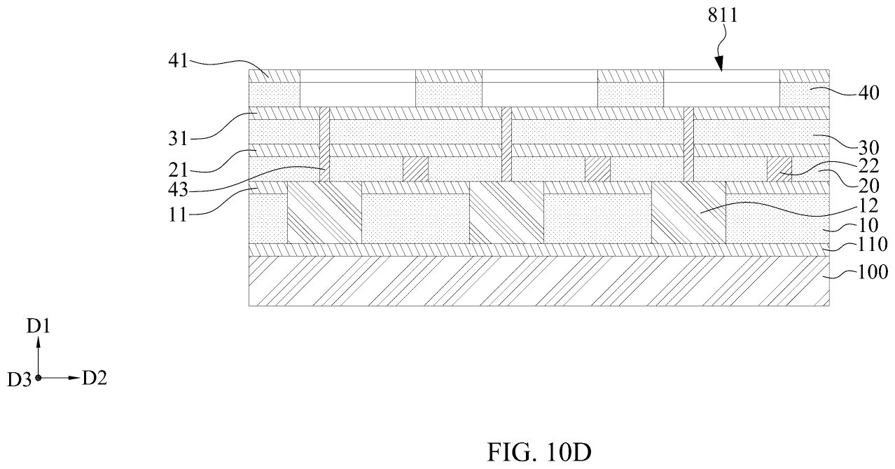

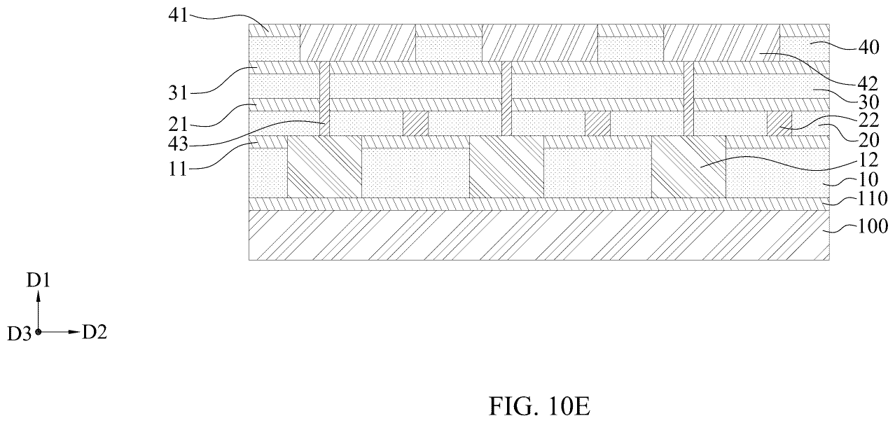

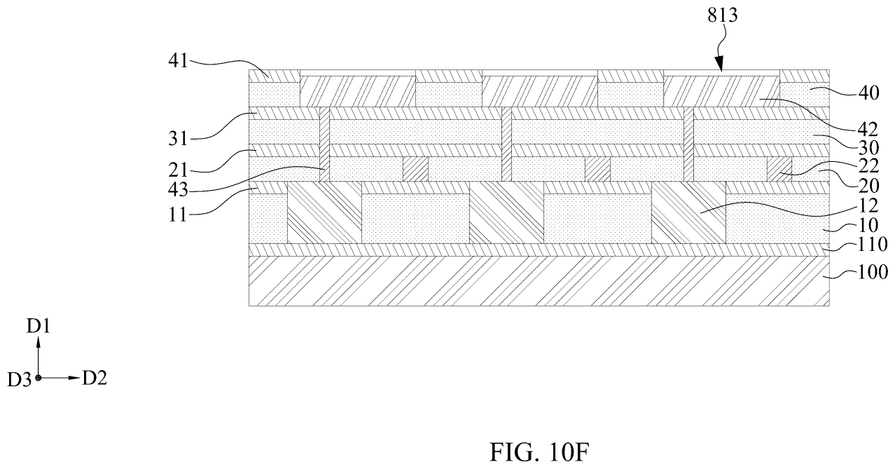

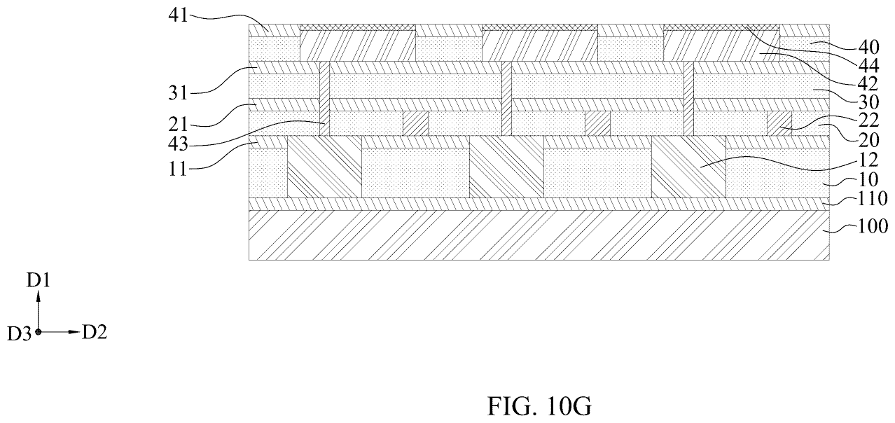

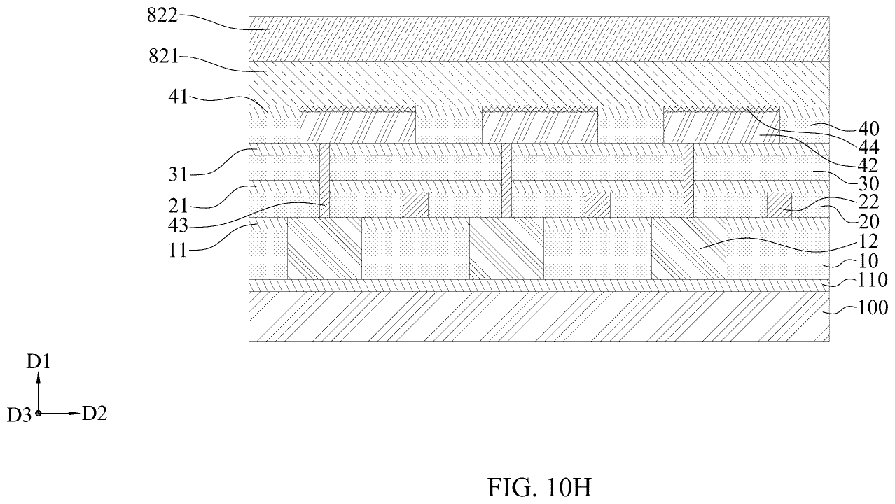

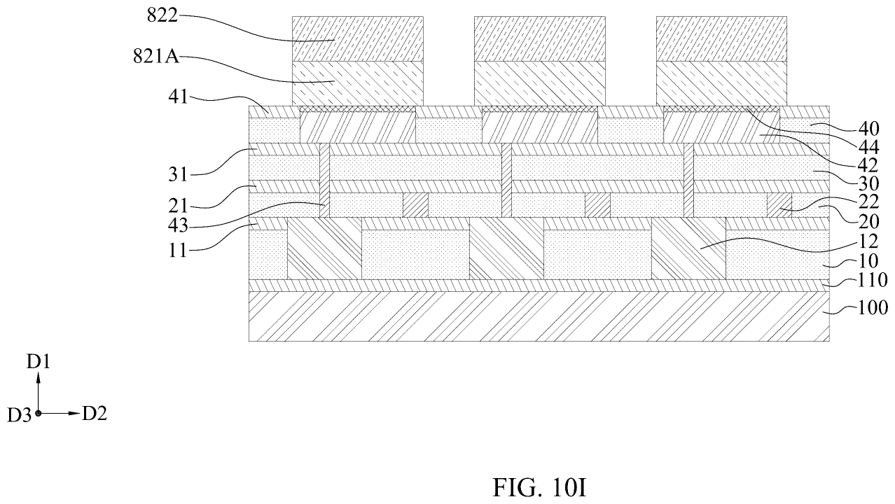

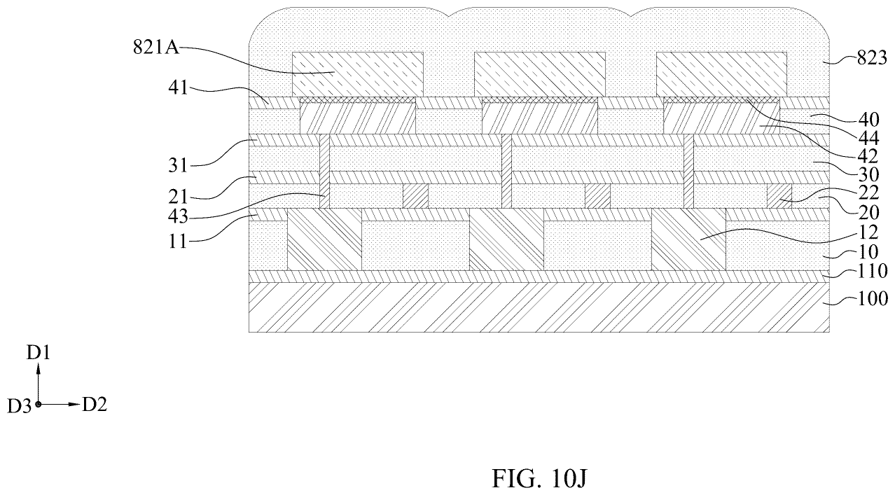

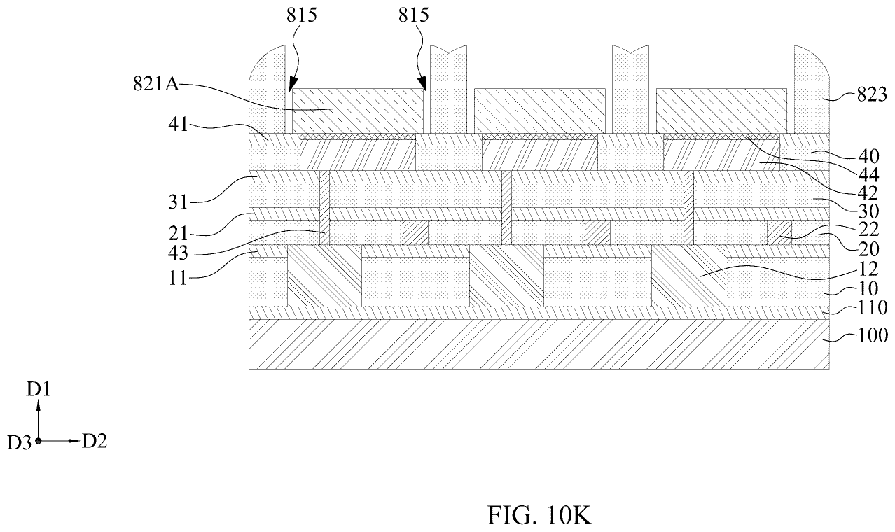

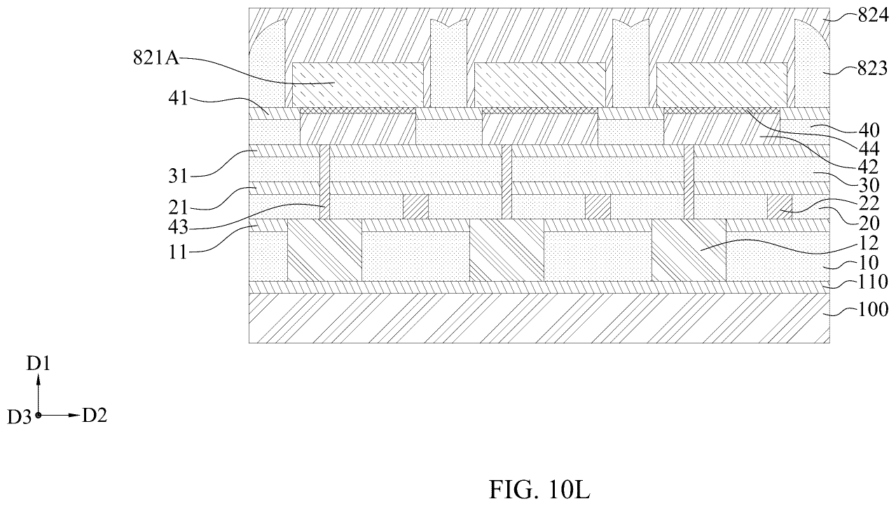

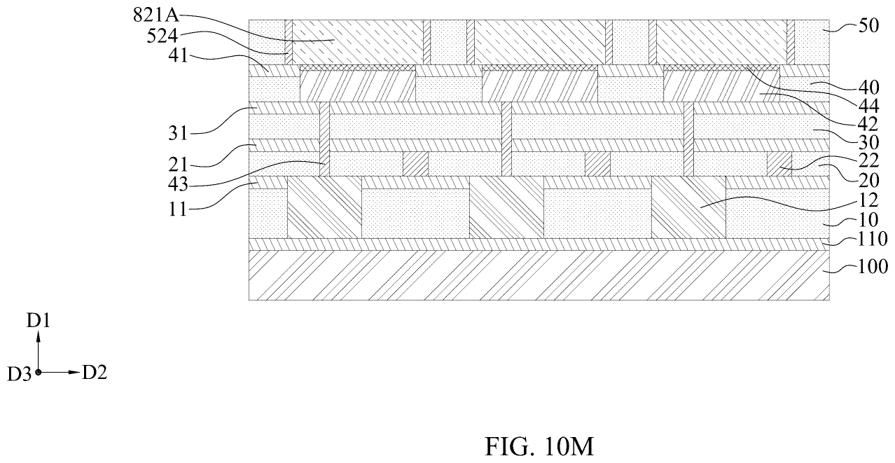

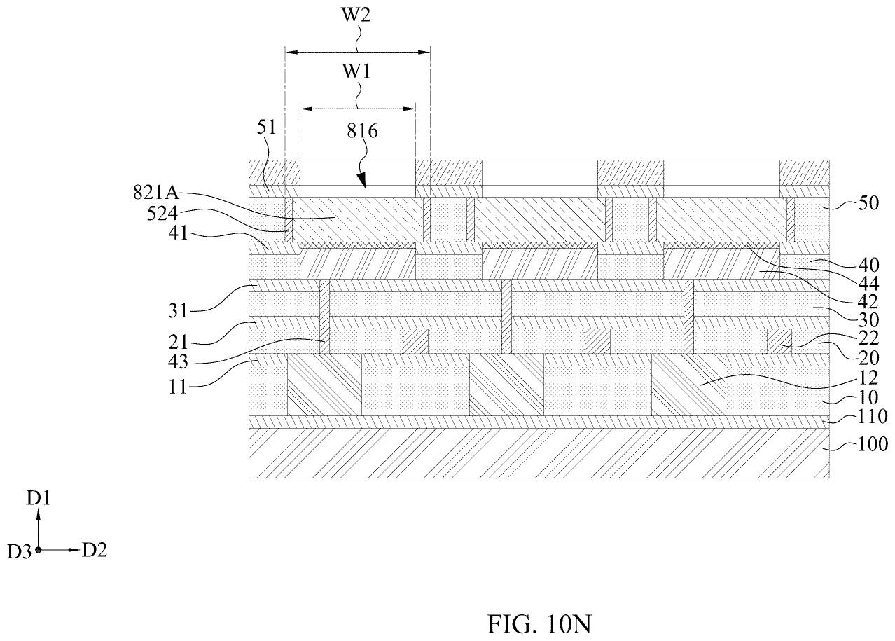

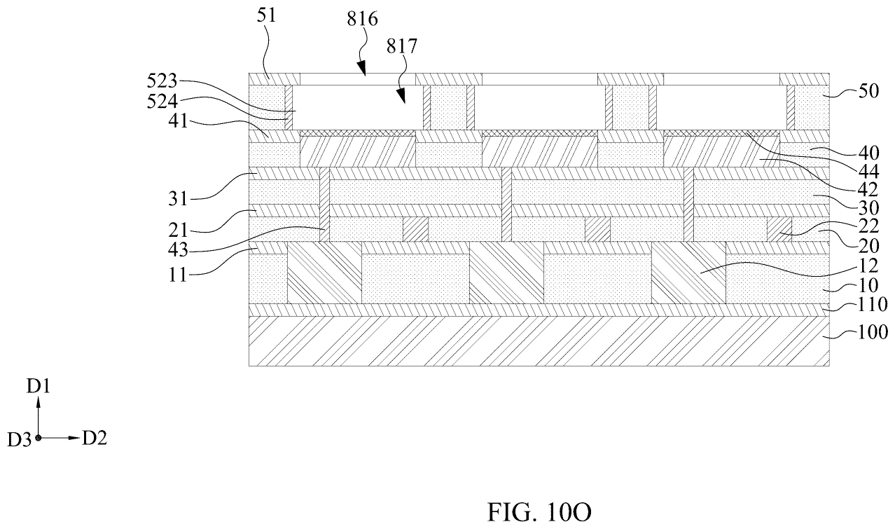

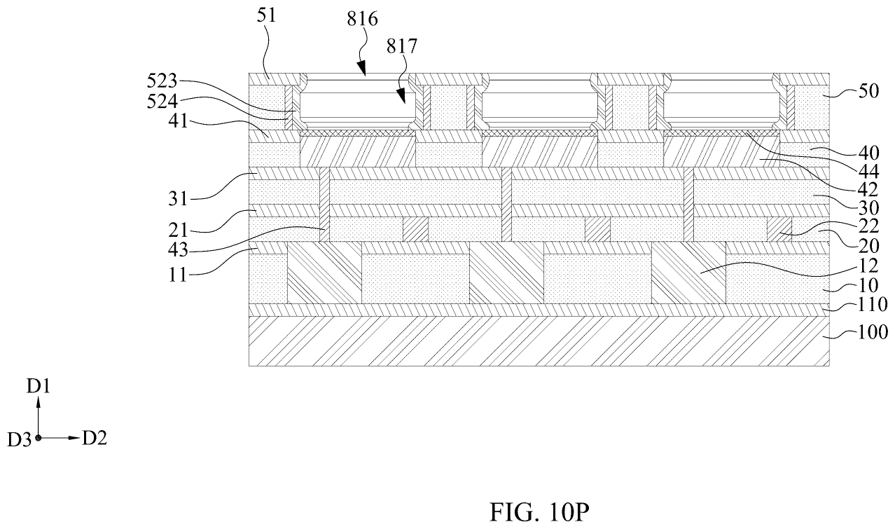

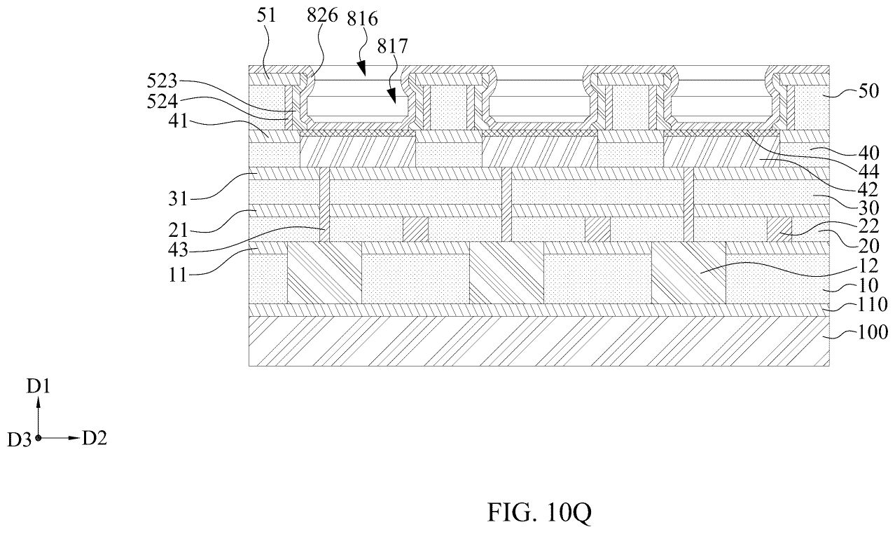

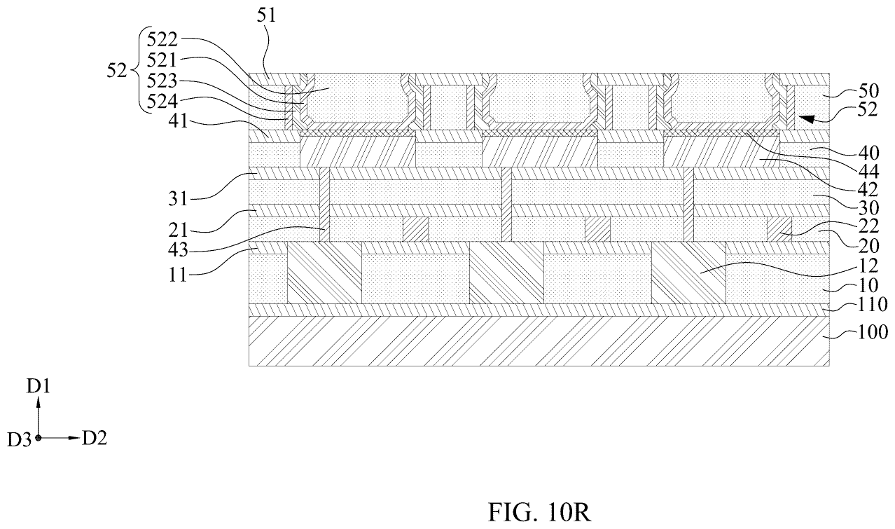

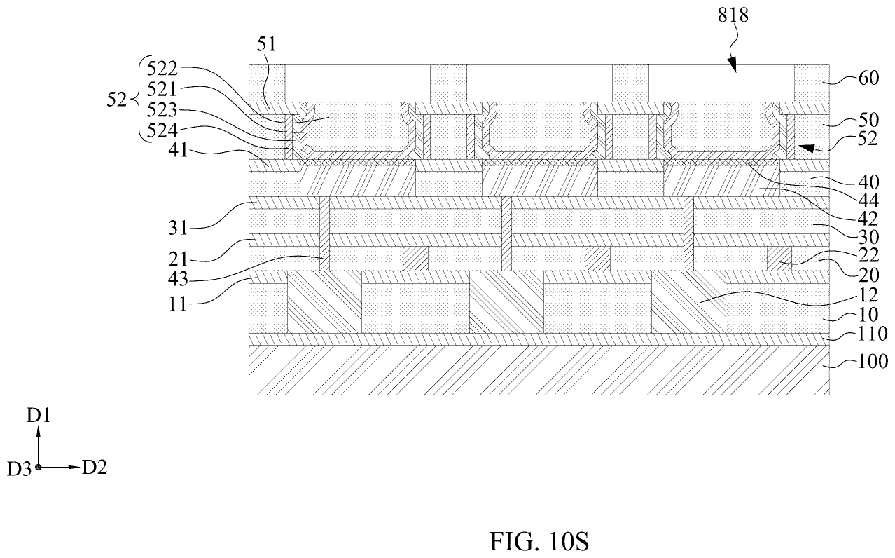

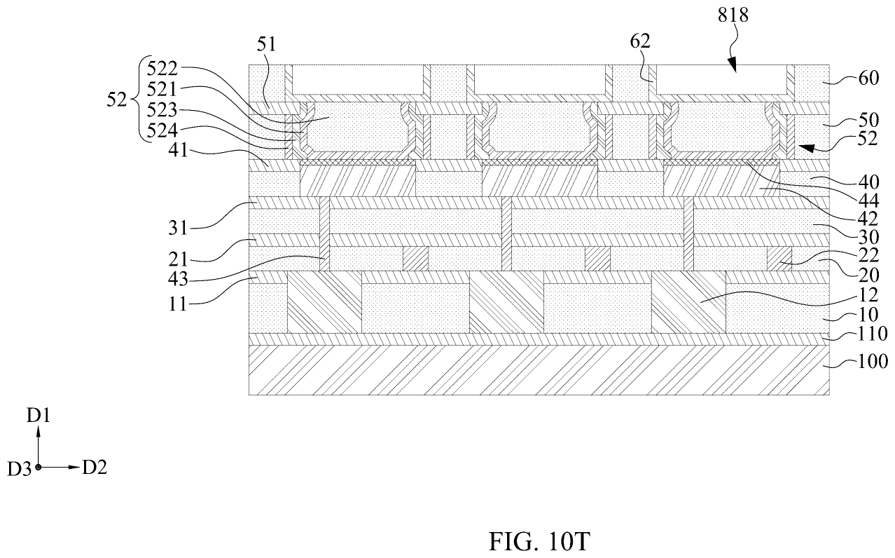

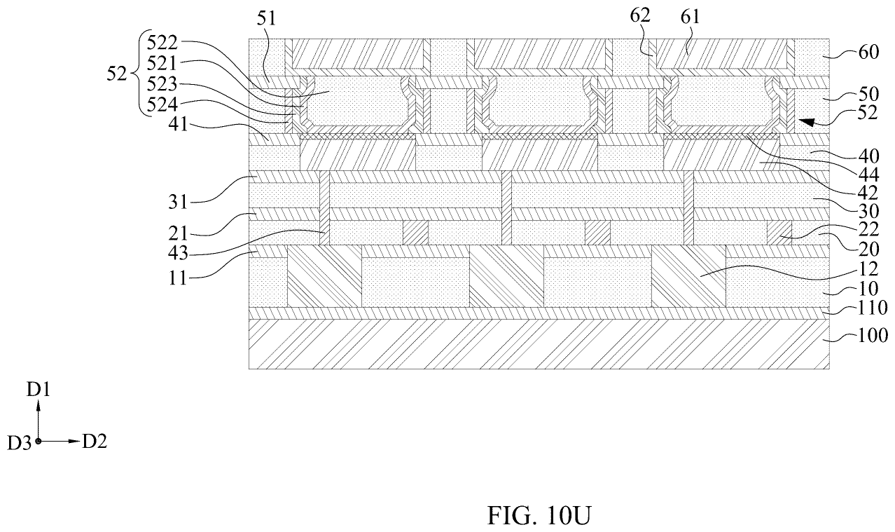

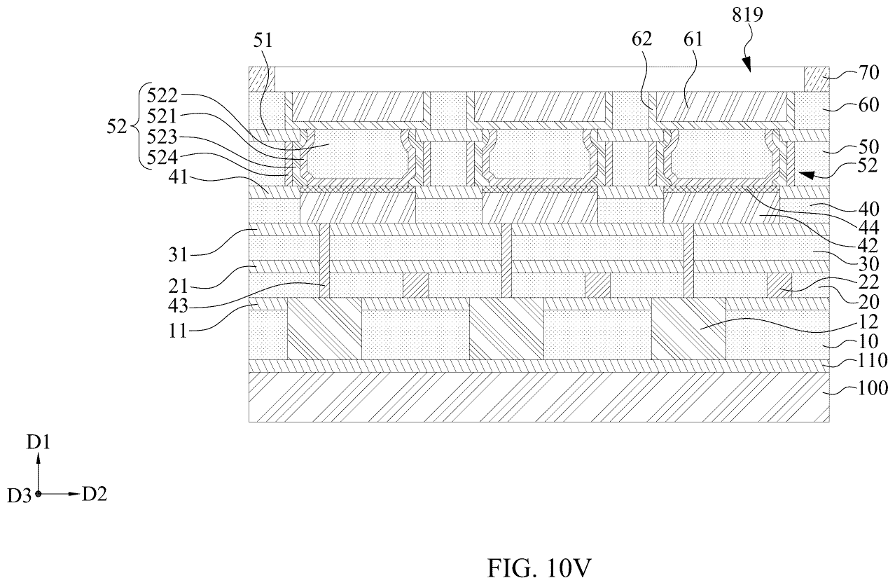

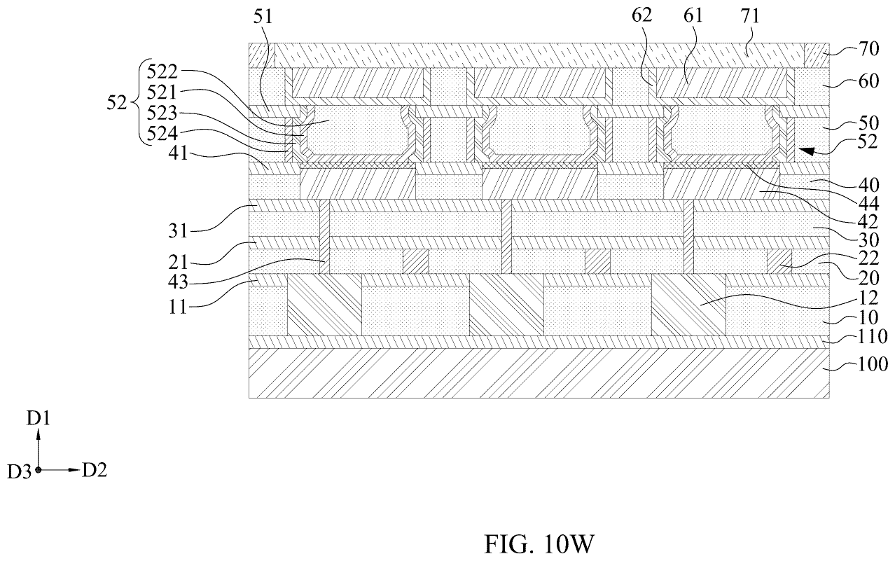

FIG. 8 is a flowchart representing a method 800 for forming a semiconductor structure according to various aspects of the present disclosure. In some embodiments, the method 800 for forming the semiconductor structure includes a number of operations (801, 802, 803, 804, 805 and 806). The method 800 for forming the semiconductor structure will be further described according to one or more embodiments. It should be noted that the operations of the method 800 may be rearranged or otherwise modified within the scope of the various aspects. It should further be noted that additional processes may be provided before, during, and after the method 800, and that some other processes may be only briefly described herein. FIGS. 9A to 9W are diagrammatic perspective views and FIGS. 10A to 10W are diagrammatic cross-sectional front views illustrating various stages in the method 800 for forming the semiconductor structure according to aspects of one or more embodiments of the present disclosure.

With reference to FIGS. 9A and 10A, the method 800 begins at operation 801 where a substrate 100 is provided or received with a first dielectric layer 10 and a first insulating layer 11 formed over the substrate 100 alone a first direction D1. A lower insulating layer 110 may be formed on the substrate 100 before the first dielectric layer 10 is formed on the substrate 100. A plurality of memory elements 12 are formed in the first dielectric layer 10 and the first insulating layer 11 so as to expose a top of each of the plurality of memory elements 12 from the first insulating layer 11.

As shown in FIGS. 9B and 10B, the method 800 continues with operation 802 where a second dielectric layer 20 are formed on the first insulating layer 11 and the plurality of memory elements 12 along the first direction D1; and a plurality of first conductive lines 22 in the second dielectric layer 20 and on the first insulating layer 11. The plurality of first conductive lines 22 can be arranged in parallel along a second direction D2, perpendicular to the first direction D1, and can be functioned as word lines (WL).

At operation 803, a second insulating layer 21, a third dielectric layer 30, a third insulating layer 31, and a fourth dielectric layer can be formed over the second dielectric layer 20 and the plurality of first conductive lines 22 in the second dielectric layer 20 along the first direction D1. As shown in FIGS. 9C and 10C, after the second insulating layer 21, the third dielectric layer 30 and the third insulating layer 31 are formed over the second dielectric layer 20 and the plurality of first conductive lines 22 in the second dielectric layer 20, a plurality of connecting lines 43 are formed by etching through the third insulating layer 31, the third dielectric layer 30, the second insulating layer 21 and the second dielectric layer 20 toward the memory elements 12; and filling conductive materials. A fourth dielectric layer 40 is formed over the third insulating layer 31 and the plurality of connecting lines 43; a fourth insulating layer 41 is applied onto the fourth dielectric layer 40; etching the fourth insulating layer 41 and the fourth dielectric layer 40 to form a plurality of first trenches 811 corresponding to the locations of the plurality of connecting lines 43 as shown in FIGS. 9D and 10D; and first conductive materials are applied to fill the first trenches 811 to form a plurality of first conductive region 42 as shown in FIGS. 9E and 10E. A planarization process (for example, but not limited to, chemical mechanical planarization (CMP)) may be performed so that a top of each of the plurality of first conductive region 42 is substantially coplanar with the fourth insulating layer 41. In some embodiments, the first conductive regions 42 may be referred to as source/drain regions. In some embodiments, the first conductive regions 42 can be referred to as source regions.

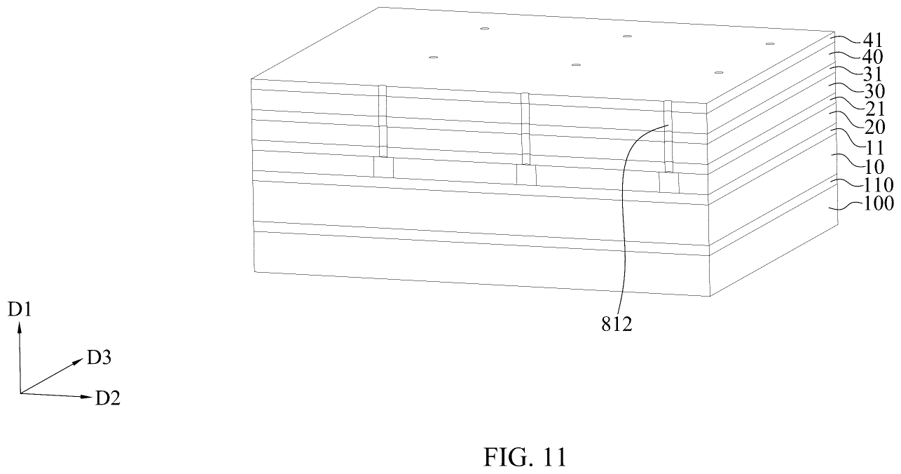

When forming the first trenches 811 through etching, a plurality of via through holes 812 can be formed by etching through the fourth insulating layer 41, the fourth dielectric layer 40, the third insulating layer 31, the third dielectric layer 30 and the second insulating layer 21 toward the first conductive lines 22 formed in the second dielectric layer 20 as shown in FIG. 9D and FIG. 11. When filling the first trenches 811 with the first conductive materials, the plurality of via through holes 812 are also filled with the first conductive materials to form vias 45 as shown in FIG. 12. In some embodiments, a parameter (i.e., a width or a diameter) dimension of the via 45 may be less than a parameter (i.e., a width or a diameter) of the first conductive region 42, but the disclosure is not limited thereto.

As shown in FIGS. 9F and 10F, each of the first conductive regions 42 can be etched from a top to form a first recess 813 surrounded by the fourth insulating layer 41. In some embodiments, the vias 45 may be partially etched to form second recesses 814. As shown in FIGS. 9G and 10G, the first recesses 813 are filled with hydrogen absorption materials to form first barrier structures 44 on the first conductive regions 42. In some embodiments, the second recesses 814 can be filled with hydrogen absorption materials to form third barrier structures 46 as shown in FIG. 12.

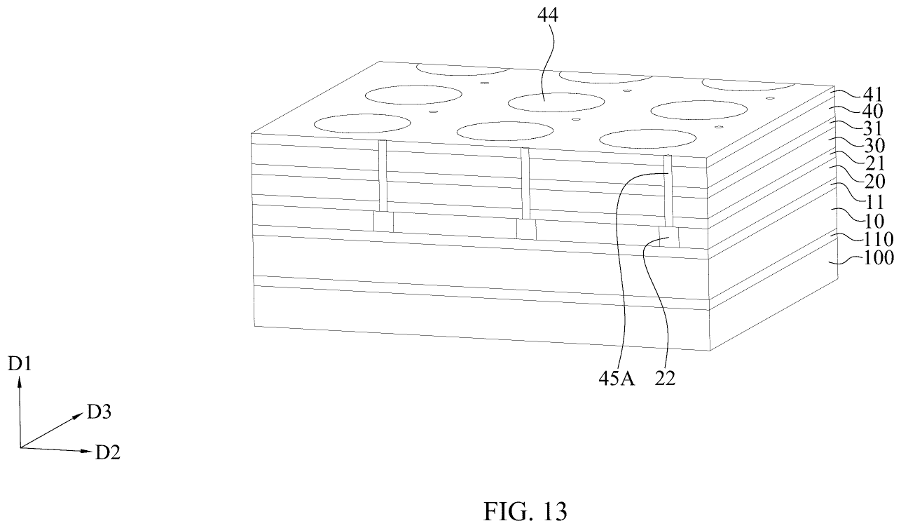

In some alternative embodiments as shown in FIG. 13, a plurality of via through holes and vias 45A may be formed after the formation of the first barrier structures 44 on the first conductive regions 42. In such embodiments, the plurality of via through holes can be formed by etching the fourth insulating layer 41, the fourth dielectric layer 40, the third insulating layer 31, the third dielectric layer 30 and the second insulating layer 21 toward the first conductive lines 22 formed in the second dielectric layer 20, and then can be filled with conductive materials to form the vias 45A, which connect the first conductive lines 22 with the gate electrodes 524 to be formed during operation 804.

In some embodiments, before filling the first trenches 811 with the first conductive materials to form a plurality of first conductive regions 42, hydrogen absorption materials may be conformally formed on the bottom and a sidewall of each of the first trenches 811 to form first barrier structures 44B as shown in FIGS. 3A and 3B. In some alternative embodiments, the first barrier structure 44C may be formed to serve as a bottom, a top and a sidewall of each of the first conductive region 42.

At operation 804 as illustrated in FIGS. 9H to 9R and 10H to 10R, a fifth dielectric layer 50 including a plurality of channel regions 52 is formed on the fourth insulating layer 41 provided on the fourth dielectric layer 40. A first sacrificial layer 821 and a first hard mask 822 are applied onto the fourth insulating layer 41 and first conductive region 42 with the first barrier structure 44 as shown in FIGS. 9H and 10H. The first hard mask 822 and the first sacrificial layer 821 are patterned to define locations for the plurality of channel regions 52 and to partially expose the fourth insulating layer 41 as shown in FIGS. 9I and 10I. The first hard mask 822 is removed; dielectric materials 823 are applied onto the patterned first sacrificial regions 821A and the exposed fourth insulating layer 41 as shown in FIGS. 9J and 10J. The dielectric materials 823 are patterned to remove portions of the dielectric materials 823 surrounding the patterned first sacrificial regions 821A to form gaps 815, which are locations for gate electrodes 524 to be formed as shown in FIGS. 9K and 10K. Conductive materials 824 are filled in the gaps 815 as shown in FIGS. 9L and 10L to form gate electrodes 524 after being planarized as shown in FIGS. 9M and 10M. Furthermore, the dielectric materials 823 form fifth dielectric layers 50 between every two of the gate electrodes 524. A layer of insulating materials and a second hard mask 825 are applied onto the fifth dielectric layer 50 with the gate electrodes 524 and the patterned first sacrificial regions 821A, which are patterned through etching to form a fifth insulating layer 51 with a plurality of third recesses 816 to partially expose a top of each of the patterned first sacrificial regions 821A as shown in FIGS. 9N and 10N. As shown in FIG. 10N, each of the third recesses 816 has a width W1, which is less than a width W2 of each of the patterned first sacrificial regions 821A.

Further in view of FIGS. 9O and 10°, the patterned first sacrificial regions 821A and the second hard mask 825 are removed to form fourth recesses 817. As shown in FIGS. 9P and 10P, gate dielectric layers 523 are conformally formed along sidewalls of the fourth recesses 817 and sidewalls of the third recesses 816 by applying dielectric materials (such as high-k dielectric materials) onto a top of the fifth insulating layer 51 and a top of the fourth insulating layer 41 and conformally on the sidewalls of the fourth recesses 817 and the sidewalls of the third recesses 816; and removing dielectric materials from the top of the fifth insulating layer 51 and those on the top of the fourth insulating layer 41. Channel layers 521 are formed on the fourth insulating layer 41 and along the gate dielectric layers 523 as shown in FIGS. 9R and 10R by applying materials 826 for forming the channel layers 521 (such as IGZO, ZnO, In₂O₃, SnO₂, and so on for an N-type channel, or NiO, Cu₂O, CuAlO₂, CuGaO₂, CuInO₂, SrCu₂O₂, SnO, and so on for a P-type channel) onto a top of the fifth insulating layer 51 and a top of the fourth insulating layer 41 and conformally along the gate dielectric layers 523 as shown in FIGS. 9Q and 10Q; and removing the materials 826 for forming the channel layers 521 from the top of the fifth insulating layer 51, so that each of the channel layers 521 has a U-shape cross section. Also in view of FIGS. 9R and 10R, central isolation structures 522 are formed in the channel layers 521. A planarization (for example, but not limited to, CMP) can be conducted, so that the channel layers 521, the central isolation structures 522, gate dielectric layers 523 and the fifth insulating layer 51 are substantially coplanar.

At operation 805 as illustrated in FIGS. 9S to 9U and 10S to 10U, a sixth dielectric layer 60 including second conductive regions 61 is formed on the fifth dielectric layer 50 and the channel regions 52. As shown in FIGS. 9S and 10S, dielectric materials are applied onto the fifth dielectric layer 50 and the channel regions 52, which are pattered through etching to form the sixth dielectric layer 60 with a plurality of second trenches 818 to expose tops of the central isolation structures 522, tops of the channel layers 521, tops of the gate dielectric layers 523 and a portion of the top of the fifth insulating layer 51. In some embodiments, a width of the second trench 818 may be greater than a width of the channel region 52. As shown in FIGS. 9T and 10T, hydrogen absorption materials are conformally applied on bottoms and sidewalls of the second trenches 818 to form second barrier structures 62. Further in view of FIGS. 9U and 10U, conductive materials are applied onto the sixth dielectric layer 60 and filled in the second trenches 818 with second barrier structures 62 to form second conductive regions 61. A planarization (for example, but not limited to, CMP) can be conducted, so that tops of the second barrier structures 62, tops of the second conductive regions 61 and a top of the sixth dielectric layer 60 are substantially coplanar.

At operation 806 as illustrated in FIGS. 9V, 9W, 10V and 10W, a seventh dielectric layer 70 including second conductive lines 71 is formed over the sixth dielectric layer 60. As shown in FIGS. 9V and 10V, dielectric materials are applied onto the sixth dielectric layer 60 and the second conductive regions 61, which are patterned through etching to form the seventh dielectric layer 70 with grooves 819 defining the locations for forming the second conductive lines 71. As shown in FIGS. 9W and 10W, conductive materials are filled in the grooves 819 to form a plurality of second conductive lines 71 arranged in parallel along a third direction D3, perpendicular to the first direction D1 and also perpendicular to the second direction D2. The plurality of second conductive lines 71 may be functioned as bit lines (BL).

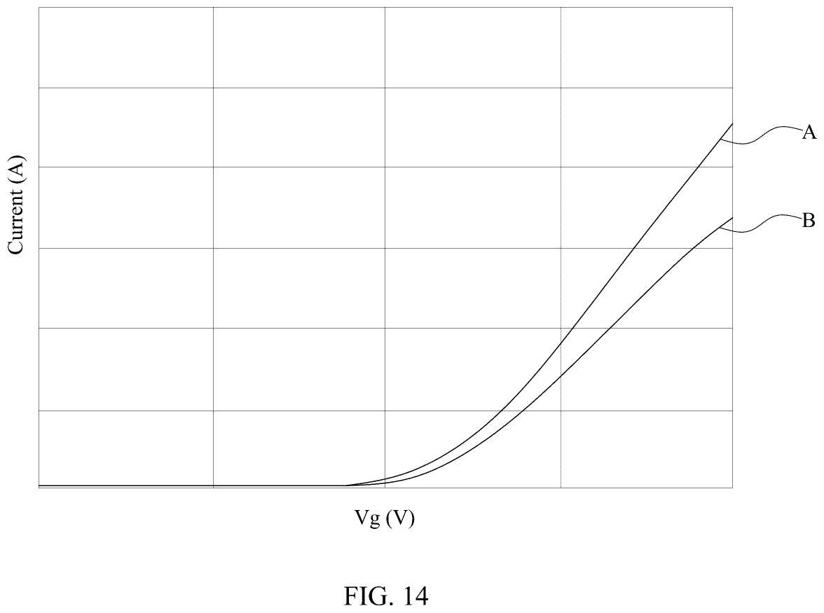

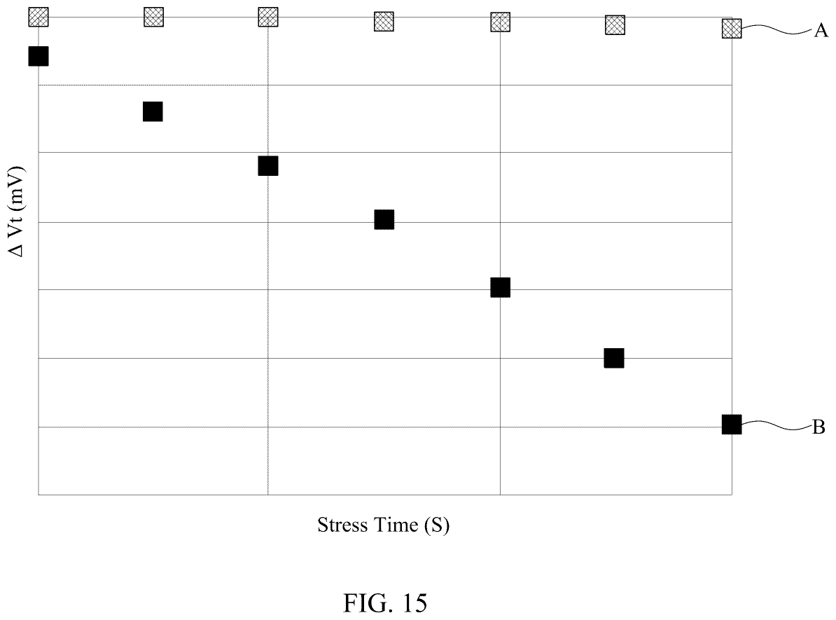

Due to the formation of the first barrier structures 44 and the second barrier structures 62, hydrogen diffusion into the channel regions 52 can be eliminated. As shown in FIG. 14, a semiconductor structure with the first and second barrier structures 44 and 62 results in reduced contact resistance and an improvement in device current (curve A) in comparison with that without barrier structures (curve B). Furthermore, FIG. 15 provides direct current (DC) NBTI stress results, which show that under DC NBTI stress, the threshold voltage (delta VT) can be substantially remained unchanged as stress time increases when a semiconductor structure with the first and second barrier structures 44 and 62 (curve A) while the threshold voltage (delta VT) significantly decreased as stress time increases when a semiconductor structure without barrier structures (curve B). Elimination of hydrogen diffusion in the channel regions reduces the contact resistance and improves device performance.

In some embodiments, a method for forming a semiconductor structure comprises: providing a substrate with a first dielectric layer including memory elements; forming a second dielectric layer over the first dielectric layer; forming a plurality of first conductive lines in the second dielectric layer; forming a third dielectric layer comprising a plurality of first trenches over the second dielectric layer; filling the plurality of first trenches with conductive materials and first hydrogen absorption materials to form a plurality of first conductive regions and a plurality of first barrier structures, wherein the plurality of first conductive regions electrically connects the memory elements; forming a fourth dielectric layer including channel regions over the third dielectric layer, wherein locations of the channel regions correspond to locations of the plurality of first conductive regions; forming a fifth dielectric layer over the fourth dielectric layer; forming a plurality of second trenches in the fifth dielectric layer; filling the plurality of second trenches with conductive materials and second hydrogen absorption materials to form a plurality of second conductive regions and a plurality of second barrier structures on the channel regions, wherein one of the plurality of first conductive regions and the plurality of second conductive regions serve as source regions, and an other of the plurality of first conductive regions and the plurality of second conductive regions serve as drain regions.

In some embodiments, a method for forming a semiconductor structure comprises forming word lines in a second dielectric layer on a first dielectric layer including memory elements, wherein the word lines are arranged in parallel along a first direction; forming a third dielectric layer over the second dielectric layer; partially etching the third dielectric layer to form a plurality of first trenches; filling the plurality of first trenches with first conductive materials and first hydrogen absorption materials to form a plurality of source regions and a plurality of first barrier structures, wherein the plurality of source regions electrically connects the memory elements; applying a first sacrificial layer onto the third dielectric layer and the plurality of source regions; patterning the first sacrificial layer to form patterned first sacrificial regions defining locations for a plurality of channel regions, which correspond locations of the source regions; applying dielectric materials onto the patterned first sacrificial regions and the third dielectric layer uncovered by the patterned first sacrificial regions; patterning the dielectric materials to remove portions of the dielectric materials to form gaps surrounding the patterned first sacrificial regions, wherein remaining portions of the dielectric materials form a fourth dielectric layer on the third dielectric layer; filling the gaps with conductive materials to form gate electrodes; applying first insulating materials onto the fourth dielectric layer, the gate electrodes and the patterned first sacrificial regions; patterning the first insulating materials to form an insulating layer with a plurality of first recesses to partially expose a top of each of the patterned first sacrificial regions; removing the patterned first sacrificial regions to form a plurality of second recesses above the source regions; conformally forming gate dielectric layers along sidewalls of the second recesses and sidewalls of the first recesses; conformally forming channel layers on the third dielectric layer and along the gate dielectric layers; filling each of the second recesses and each of the first recesses with a second insulating materials so as to form a central isolation structure with the channel layer 521 as a bottom and a sidewall; forming a fifth dielectric layer over the fourth dielectric layer; etching the fifth dielectric layer to form a plurality of second trenches; and filling the plurality of second trenches with second conductive materials and second hydrogen absorption materials to form a plurality of drain regions and a plurality of second barrier structures on the channel regions.

In some embodiments, a semiconductor structure comprises: a first dielectric layer comprising a plurality of memory elements; a second dielectric layer stacking over the first dielectric layer along a first direction and comprising a plurality of first conductive lines arranged in parallel along a second direction, perpendicular to the first direction; a third dielectric layer stacking over the second dielectric layer along the first direction and comprising: a plurality of first conductive regions electrically connecting the memory elements; and a plurality of first barrier structures formed on bottoms or tops of the plurality of first conductive regions; a fourth dielectric layer stacking over third dielectric layer and comprising channel regions, each of the channel regions comprising: a central portion comprising a central isolation structure and a channel layer, wherein the channel layer electrically connects a corresponding one of the first conductive regions; a gate dielectric layer formed around the channel layer so that the channel layer is sandwiched by the gate dielectric layer and the central isolation structure; and a gate electrode formed along the gate dielectric layers and electrically connecting the plurality of first conductive lines; a fifth dielectric layer stacking over the fourth dielectric layer along the first direction and comprising: a plurality of second conductive regions electrically connecting the channel layer; and a plurality of second barrier structures formed on the central portions of the channel regions, wherein the gate electrode is formed between the third dielectric layer and the fourth dielectric layer, and wherein the plurality of first barrier structures and the plurality of second barrier structures comprise hydrogen absorption materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for manufacturing a semiconductor structure, comprising:
providing a substrate with a first dielectric layer including memory elements;
forming a second dielectric layer over the first dielectric layer;
forming a plurality of first conductive lines in the second dielectric layer;
forming a third dielectric layer comprising a plurality of first trenches over the second dielectric layer;
filling the plurality of first trenches with conductive materials and first hydrogen absorption materials to form a plurality of first conductive regions and a plurality of first barrier structures, wherein the plurality of first conductive regions electrically connects the memory elements;
forming a fourth dielectric layer including channel regions over the third dielectric layer, wherein locations of the channel regions correspond to locations of the plurality of first conductive regions;
forming a fifth dielectric layer over the fourth dielectric layer;
forming a plurality of second trenches in the fifth dielectric layer;
filling the plurality of second trenches with conductive materials and second hydrogen absorption materials to form a plurality of second conductive regions and a plurality of second barrier structures on the channel regions,
wherein one of the plurality of first conductive regions and the plurality of second conductive regions serve as source regions, and an other of the plurality of first conductive regions and the plurality of second conductive regions serve as drain regions.

2. The method of claim 1, wherein forming the plurality of first conductive regions and the plurality of first barrier structures comprises:
filling the plurality of first trenches with the conductive materials to form the plurality of first conductive regions;
etching top portions of the plurality of first conductive regions to form a plurality of first recesses; and
filling the plurality of first recesses with the first hydrogen absorption materials to form the plurality of first barrier structures on the plurality of first conductive regions.

3. The method of claim 2, wherein each of the plurality of first barrier structures has a rectangular cross section or an inverted-trapezoid cross section.

4. The method of claim 1, wherein forming the plurality of first conductive regions and the plurality of first barrier structures comprises:
conformally applying the first hydrogen absorption materials on bottoms and sidewalls of the first trenches to form the first conductive regions; and
filling the plurality of first trenches with the conductive materials to form the plurality of second conductive regions.

5. The method of claim 1, wherein forming the plurality of first conductive regions and the plurality of first barrier structures comprises:
conformally applying the first hydrogen absorption materials on bottoms and sidewalls of the first trenches to form lower portions the first conductive regions;
filling the plurality of first trenches with the conductive materials to form the plurality of second conductive regions;
etching top portions of the plurality of first conductive regions to form a plurality of first recesses; and
filling the plurality of first recesses with the first hydrogen absorption materials to form upper portions of the plurality of first barrier structures on the plurality of first conductive regions, so that each of the plurality of first barrier structures surround each of the plurality of first recesses.

6. The method of claim 1, wherein forming the plurality of second conductive regions and a plurality of second barrier structures on the channel regions comprises:
conformally applying second hydrogen absorption materials on bottoms and sidewalls of the second trenches to form the second barrier structures; and
filling the plurality of second trenches with the conductive materials to form the plurality of second conductive regions.

7. The method of claim 1, wherein forming the plurality of second conductive regions and a plurality of second barrier structures on the channel regions comprises:
conformally applying second hydrogen absorption materials on bottoms and sidewalls of the second trenches to form the second barrier structures;
filling the plurality of second trenches with the conductive materials to form the plurality of second conductive regions;
etching top portions of the plurality of second conductive regions to form a plurality of second recesses; and
filling the plurality of second recesses with the second hydrogen absorption materials to form upper portions of the plurality of second barrier structures on the plurality of second conductive regions, so that each of the plurality of second barrier structures surround each of the plurality of second conductive regions.

8. The method of claim 1, wherein the first hydrogen absorption materials comprise indium oxide, titanium oxide, indium tin oxide (ITO), cerium oxide, zinc oxide, indium gallium zinc oxide (IGZO), or a combination thereof; and the second hydrogen absorption materials comprise indium oxide, titanium oxide, indium tin oxide (ITO), cerium oxide, zinc oxide, indium gallium zinc oxide (IGZO), or a combination thereof.

9. A method for manufacturing a semiconductor structure, comprising:
forming word lines in a second dielectric layer on a first dielectric layer including memory elements, wherein the word lines are arranged in parallel along a first direction;
forming a third dielectric layer over the second dielectric layer;
partially etching the third dielectric layer to form a plurality of first trenches;
filling the plurality of first trenches with first conductive materials and first hydrogen absorption materials to form a plurality of source regions and a plurality of first barrier structures, wherein the plurality of source regions electrically connects the memory elements;
applying a first sacrificial layer onto the third dielectric layer and the plurality of source regions;
patterning the first sacrificial layer to form patterned first sacrificial regions defining locations for a plurality of channel regions, which correspond locations of the source regions;
applying dielectric materials onto the patterned first sacrificial regions and the third dielectric layer uncovered by the patterned first sacrificial regions;
patterning the dielectric materials to remove portions of the dielectric materials to form gaps surrounding the patterned first sacrificial regions, wherein remaining portions of the dielectric materials form a fourth dielectric layer on the third dielectric layer;
filling the gaps with conductive materials to form gate electrodes;
applying first insulating materials onto the fourth dielectric layer, the gate electrodes and the patterned first sacrificial regions;
patterning the first insulating materials to form an insulating layer with a plurality of first recesses to partially expose a top of each of the patterned first sacrificial regions;
removing the patterned first sacrificial regions to form a plurality of second recesses above the source regions;
conformally forming gate dielectric layers along sidewalls of the second recesses and sidewalls of the first recesses;
conformally forming channel layers on the third dielectric layer and along the gate dielectric layers;
filling each of the second recesses and each of the first recesses with a second insulating materials so as to form a central isolation structure with the channel layer as a bottom and a sidewall;
forming a fifth dielectric layer over the fourth dielectric layer;
etching the fifth dielectric layer to form a plurality of second trenches; and
filling the plurality of second trenches with second conductive materials and second hydrogen absorption materials to form a plurality of drain regions and a plurality of second barrier structures on the channel regions.

10. The method of claim 9, further comprising:
forming a sixth dielectric layer over the fifth dielectric layer after forming the plurality of drain regions and the plurality of second barrier structures on the channel regions;
partially etching the sixth dielectric layer to form a plurality of grooves; and
filling the plurality of grooves with conductive materials to form a plurality of bit lines in the sixth dielectric layer,
wherein the plurality of bit lines arranged in parallel along a second direction, perpendicular to the first direction.

11. The method of claim 9, wherein each of the plurality of first recesses has a width, which is less than a width of each of the patterned first sacrificial regions.

12. The method of claim 9, further comprising:
forming a plurality of via through holes by etching through the third dielectric layer toward the word lines formed in the second dielectric layer when forming the plurality of first trenches; and
filling the plurality of via through holes with the conductive materials to form word line vias when filling the plurality of first trenches with conductive materials to form the plurality of source regions, so that the gate electrodes electrically connects the word lines through the word line vias,
wherein the word line vias comprise the conductive materials, which is identical to the conductive materials of the plurality of source regions.

13. The method of claim 9, further comprising:
forming a plurality of via through holes by etching through the third dielectric layer toward the word lines formed in the second dielectric layer after the plurality of source regions and the plurality of first barrier structures are formed; and
filling the plurality of via through holes with conductive materials to form word line vias,
wherein the word line vias comprise the conductive materials, which is identical to or different from the conductive materials of the plurality of source regions.

14. The method of claim 9, wherein the channel layer comprises a first channel sublayer and a second channel sublayer, and wherein the first channel sublayer has a dopant concentration, which is different from a dopant concentration of the second channel sublayer.

15. A semiconductor structure, comprising:
a first dielectric layer comprising a plurality of memory elements;
a second dielectric layer stacking over the first dielectric layer along a first direction and comprising a plurality of first conductive lines arranged in parallel along a second direction, perpendicular to the first direction;
a third dielectric layer stacking over the second dielectric layer along the first direction and comprising:
a plurality of first conductive regions electrically connecting the memory elements; and
a plurality of first barrier structures formed on bottoms or tops of the plurality of first conductive regions;
a fourth dielectric layer stacking over third dielectric layer and comprising channel regions, each of the channel regions comprising:
a central portion comprising a central isolation structure and a channel layer, wherein the channel layer electrically connects a corresponding one of the first conductive regions;
a gate dielectric layer formed around the channel layer so that the channel layer is sandwiched by the gate dielectric layer and the central isolation structure; and
a gate electrode formed along the gate dielectric layers and electrically connecting the plurality of first conductive lines;
a fifth dielectric layer stacking over the fourth dielectric layer along the first direction and comprising:
a plurality of second conductive regions electrically connecting the channel layer; and
a plurality of second barrier structures formed on the central portions of the channel regions,
wherein the gate electrode is formed between the third dielectric layer and the fourth dielectric layer, and
wherein the plurality of first barrier structures and the plurality of second barrier structures comprise hydrogen absorption materials.

16. The semiconductor structure of claim 15, wherein each of the first barrier structure is formed on the first conductive region and is sandwiched by the first conductive region and the channel layer.

17. The semiconductor structure of claim 16, wherein each of the plurality of first barrier structures has a rectangular cross section or an inverted-trapezoid cross section.

18. The semiconductor structure of claim 15, wherein the first barrier structure is formed on a bottom and a sidewall of the first conductive region or formed on a top, a bottom and a sidewall of the first conductive region.

19. The semiconductor structure of claim 15, wherein the second barrier structure is formed on a bottom and a sidewall of the second conductive regions or formed on a top, a bottom and a sidewall of the second conductive regions.

20. The semiconductor structure of claim 15, further comprises a plurality of second conductive lines on the fifth dielectric layer, which electrically connect the second conductive regions and are arranged in parallel along a third direction, perpendicular to the first direction and also perpendicular to the second direction.
